(19) United States
(12) Patent Application Publication
(10) Pub. No.: US 2016/0241148 A1
(43) Pub. Date: Aug. 18, 2016

(54) METHOD AND SYSTEM FOR INTEGRATED POWER SUPPLY WITH ACCESSORY FUNCTIONS

(71) Applicant: Avogy, Inc., San Jose, CA (US)

(72) Inventors: Isik Kizilyalli, San Jose, CA (US); Dinesh Ramanathan, San Jose, CA (US); Rob Levine, San Jose, CA (US); Mikhail Guz, San Jose, CA (US)

(21) Appl. No.: 15/042,421

(22) Filed: Feb. 12, 2016

Related U.S. Application Data
(60) Provisional application No. 62/115,743, filed on Feb. 13, 2015.

(51) Int. Cl. H02M 3/335; H05K 5/02; H02M 7/00

(52) U.S. Cl. CPC H02M 3/33507; H02M 7/003; H05K 5/0247

(57) ABSTRACT

A variable output power supply includes a power unit comprising a housing including an output port, one or more accessories disposed in the housing, and a controller disposed in the housing and in communication with the output port. The variable output power supply also includes a power cable. The controller is operable to modify operation of the output port in response, at least in part, to insertion of the power cable in the output port.

### CROSS-REFERENCES TO RELATED APPLICATIONS

This application claims priority to U.S. Provisional Patent Application No. 62/115,743, filed on Feb. 13, 2015, entitled “Method and System for Integrated Power Supply with Accessory Functions,” the disclosure of which is hereby incorporated by reference in its entirety for all purposes.

### BACKGROUND OF THE INVENTION

Mobile electronic devices, such as portable computers, tablets, smart phones, electronic book readers, and the like, are becoming increasingly popular. These mobile devices are typically powered by batteries. Power adapters (e.g., alternating current (AC) power adapters) are typically provided in conjunction with mobile electronic devices so that the mobile devices can be powered by or recharged using an electrical outlet.

Despite the progress made in power adapters for mobile devices, there is a need in the art for improved methods and systems related to power supplies.

### SUMMARY OF THE INVENTION

The present invention relates generally to electronic devices. Embodiments of the present invention provide power supplies with integrated accessory functions. More particularly, embodiments of the present invention include a power supply with at least one variable output voltage port and at least one integrated accessory. The present invention has wider applicability beyond power supplies to include other electronic devices.

According to an embodiment of the present invention, a variable output power supply is provided. The variable output power supply includes a power unit comprising a housing including an output port, one or more accessories disposed in the housing, and a controller disposed in the housing and in communication with the output port. The variable output power supply also includes a power cable. The controller is operable to modify operation of the output port in response, at least in part, to insertion of the power cable in the output port.

According to another embodiment of the present invention, a method of operating a variable output power supply including an AC adapter and a battery is provided. The method includes setting an output voltage of an output of the variable output power supply to a default voltage and determining a configuration of an output cable. The method also includes modifying the output voltage of the output of the variable output power supply as a function of the cable configuration and coupling either the AC adapter or the battery to the output of the variable output power supply.

Numerous benefits are achieved by way of the present invention over conventional techniques. For example, embodiments of the present invention provide a power supply that operates at multiple output voltages while also providing accessory functions in an integrated package. Additionally, embodiments of the present invention provide a user with the ability to charge multiple devices concurrently or simultaneously even though the combined power requirements of the devices being charged exceeds the power rating of the power adapter, accelerate the charging process, charge more important devices faster than others, and reduce energy consumption. These and other embodiments of the present invention, along with many of its advantages and features, are described in more detail in conjunction with the text below and attached figures.

### BRIEF DESCRIPTION OF THE DRAWINGS

FIG. 1A is perspective diagram of a power unit of a variable output power supply and a power cable according to an embodiment of the present invention.

FIG. 1B is a perspective view of a power cable connected to a power unit of a variable output power supply according to an embodiment of the present invention.

FIG. 1C is a perspective view of a power cable unable to connect to a power unit of a variable output power supply according to an embodiment of the present invention.

FIG. 1D is a perspective view of a single output power unit according to an embodiment of the present invention.

FIG. 2 is a drawing illustrating a keyed power cable according to an embodiment of the present invention.

FIG. 3A is a simplified schematic diagram of the power unit of the variable output power supply according to an embodiment of the present invention.

FIG. 3B is a simplified schematic diagram of the power unit of the variable output power supply according to a particular embodiment of the present invention.

FIG. 3C is a simplified schematic diagram of a single output implementation of the power unit of the variable output power supply according to an embodiment of the present invention.

FIG. 3D is a simplified schematic diagram of another single output implementation of the power unit of the variable output power supply according to an embodiment of the present invention.

FIG. 3E is a simplified schematic diagram of yet another single output implementation of the power unit of the variable output power supply according to an embodiment of the present invention.

FIG. 3F is a simplified schematic diagram of a dual output implementation of the power unit of the variable output power supply according to an embodiment of the present invention.

FIG. 3G is a simplified schematic diagram of another dual output implementation of the power unit of the variable output power supply according to an embodiment of the present invention.

FIG. 4 is a schematic diagram illustrating a pin configuration for a power cable according to an embodiment of the present invention.

FIG. 5 is a simplified flowchart illustrating a method of operating the variable output power supply according to an embodiment of the present invention.

FIG. 6 is a simplified schematic diagram illustrating a power supply with an integrated battery according to an embodiment of the present invention.

FIG. 7 is a simplified schematic diagram illustrating a power supply with one or more integrated accessories according to an embodiment of the present invention.

FIG. 8 is a simplified schematic diagram illustrating interaction between a mobile application and a power adapter according to an embodiment of the present invention.

FIG. 9 is perspective diagram of a variable output power supply and a power cable suitable for use with embodiments of the present invention.

FIG. 10 is a simplified graphical user interface illustrating system settings according to an embodiment of the present invention.

FIG. 11 is a simplified graphical user interface illustrating system priority settings according to an embodiment of the present invention.

FIG. 12A is a simplified graphical user interface after setting charging priority according to an embodiment of the present invention.

FIG. 12B is a simplified graphical user interface illustrating charging priority and charging thresholds according to an embodiment of the present invention.

FIG. 13 is a simplified graphical user interface illustrating scheduling of charging according to an embodiment of the present invention.

FIG. 14 is a simplified graphical user interface illustrating scheduling charge start time according to an embodiment of the present invention.

FIG. 15 is a simplified graphical user interface illustrating monitoring of device charging according to an embodiment of the present invention.

FIG. 16 is a simplified graphical user interface illustrating LED operation according to an embodiment of the present invention.

FIG. 17 is a simplified graphical user interface illustrating scheduling of LED operation according to an embodiment of the present invention.

FIG. 18 is a simplified graphical user interface illustrating scheduling of LED extinguishing according to an embodiment of the present invention.

FIG. 19 is a simplified flowchart illustrating a method of operating a power adapter having multiple outputs according to an embodiment of the present invention.

### DETAILED DESCRIPTION OF SPECIFIC EMBODIMENTS

The present invention relates generally to electronic devices. More specifically, the present invention relates to a power supply that is operable to output different voltages (and/or wattage) in response to the type of power cable that is connected to the output connector of the power supply. In a particular embodiment, an output connector that initially operates as a standard 5 V USB output connector is modified to operate at 19.5 V in response to a special cable being connected to the output connector.

According to an embodiment of the present invention, a power supply is provided that includes a port with a keyed opening (i.e., a keyhole) that is operable to receive a power cable with a matching key. When the power cable is connected to the port, the power supply detects the configuration of the power cable and adjusts the output of the port accordingly. Thus, the voltage of the power supply is a function of or is dependent on the configuration of the power cable.

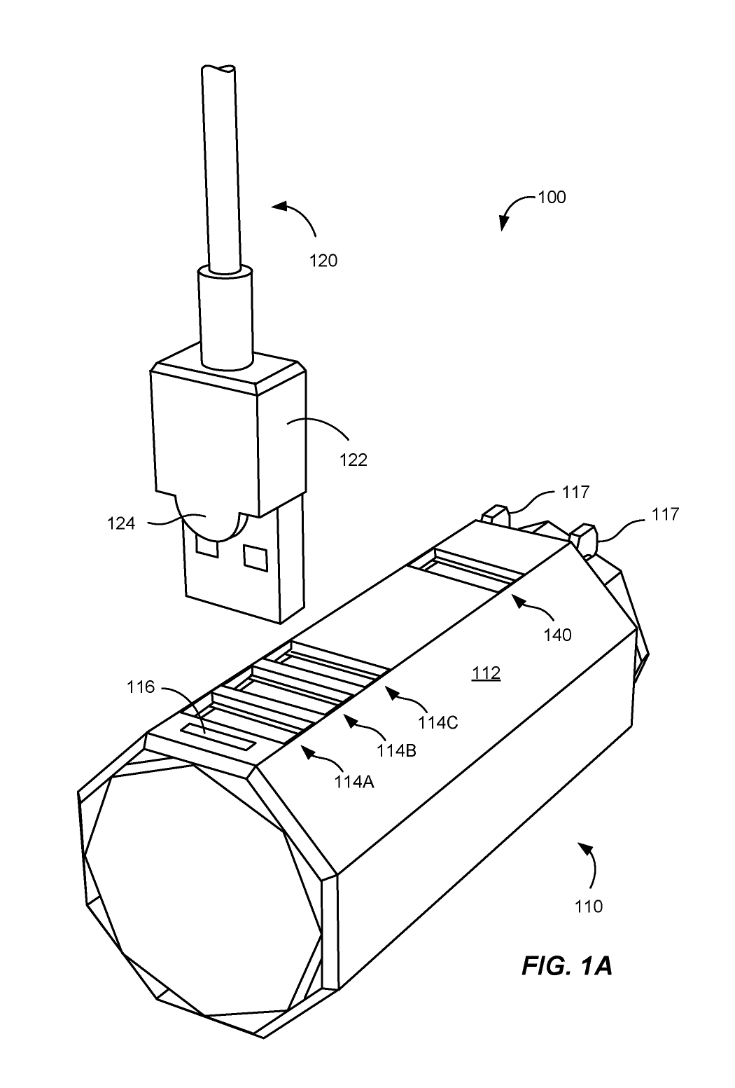

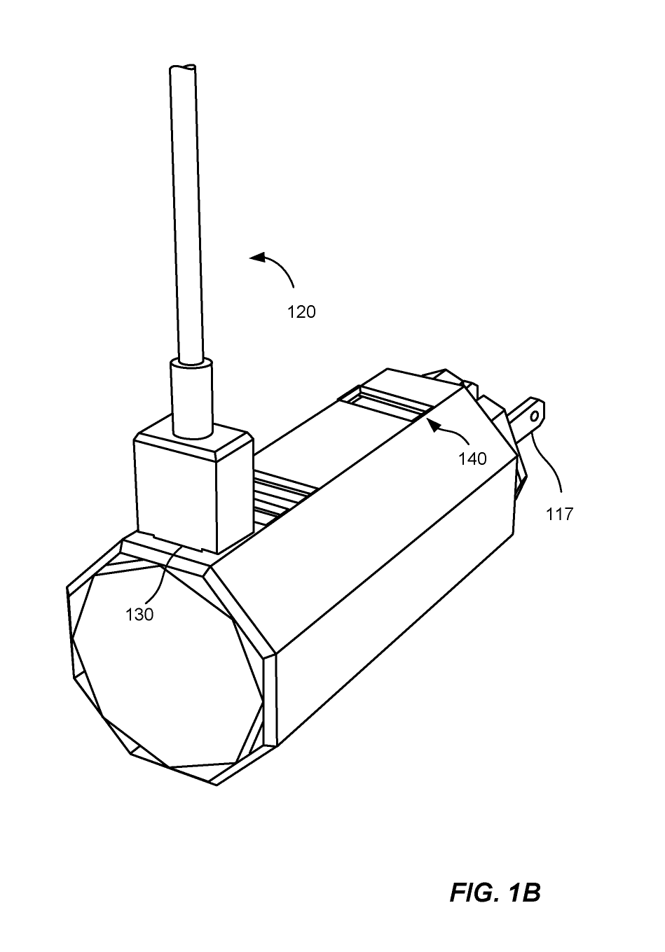

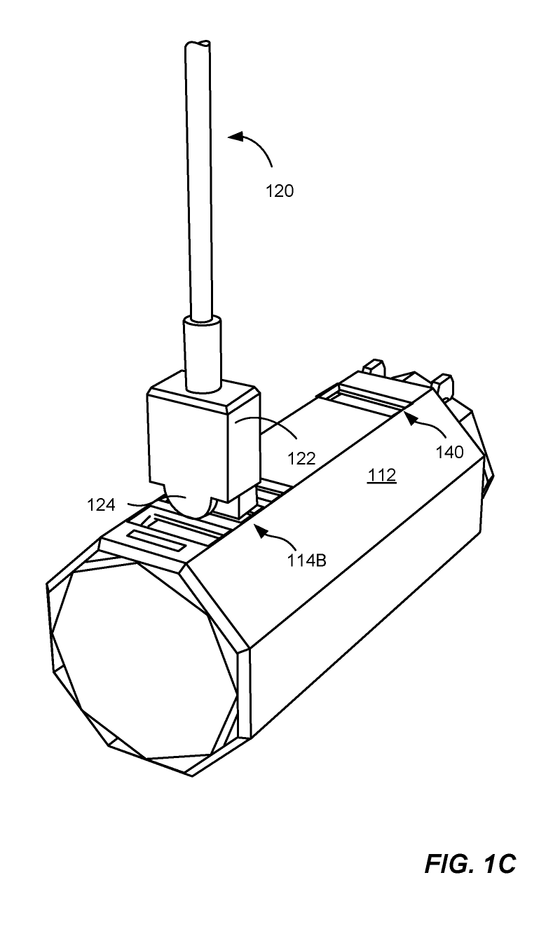

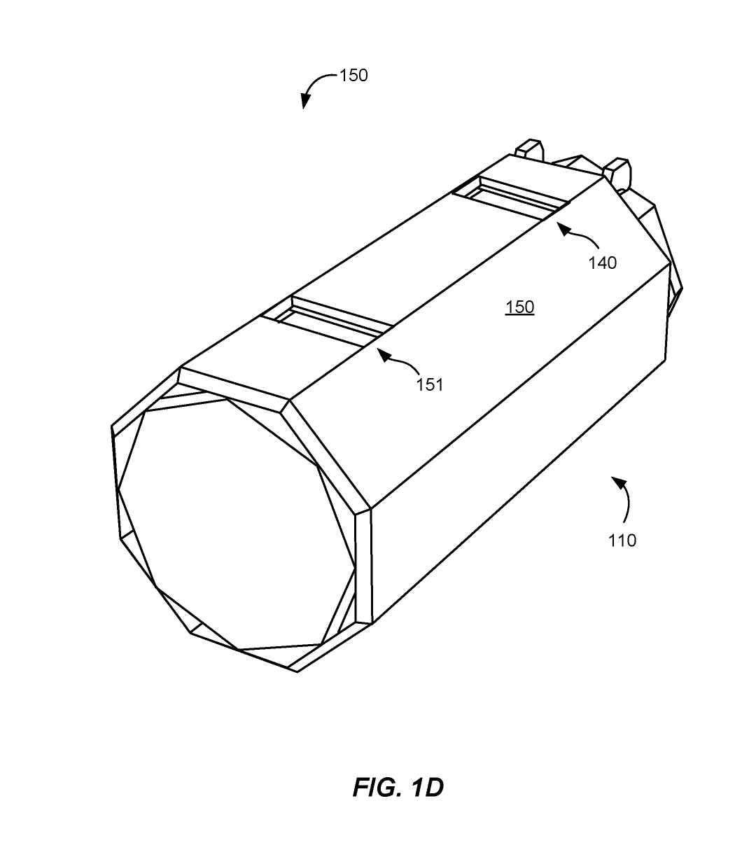

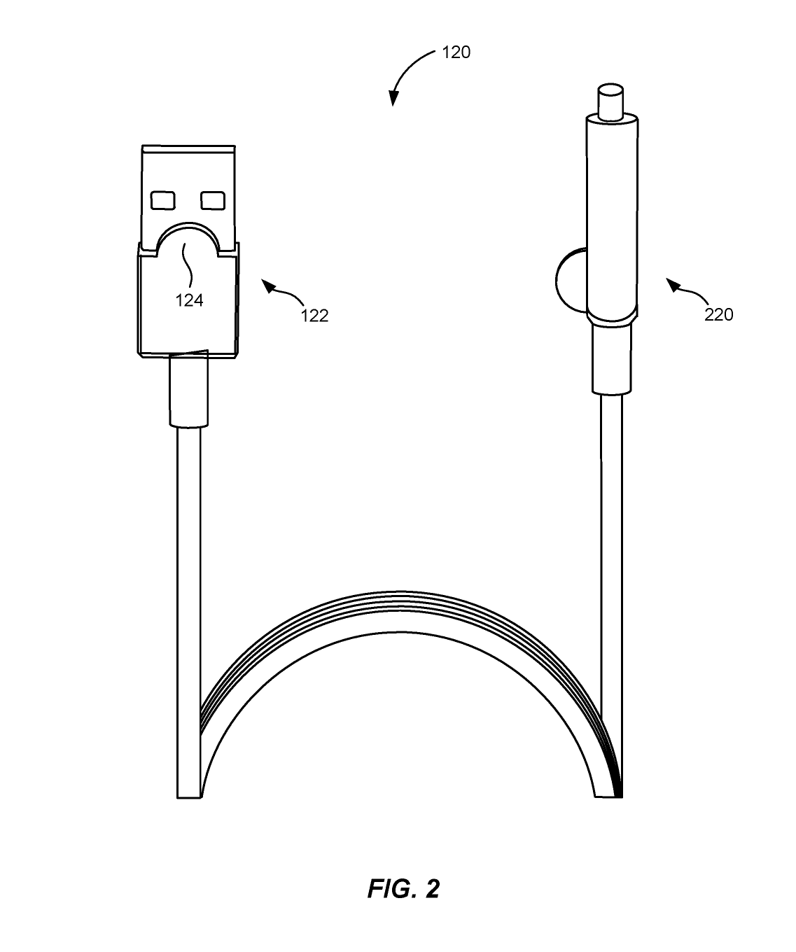

FIG. 1A is perspective diagram of a variable output power supply including one or more accessories and a power cable according to an embodiment of the present invention. As illustrated in FIG. 1A, the variable output power supply 100 includes a power unit 110 and a power cable 120. Additional description related to power cable 120 is illustrated in FIG. 2. The power unit 110 includes a housing 112 and a plurality of output ports 114A, 114B, and 114C, also referred to as output connections. In the illustrated embodiment, there are three output ports, but this is not required by embodiments of the present invention and other number of output ports, including one, two, four, five, six, or more, are included within the scope of the present invention.

As described more fully herein, the plurality of output ports 114A, 114B, and 114C differ, with one or more of the output ports providing a variable voltage output depending on the type of power cable connected to the output connection. In some embodiments, one of the plurality of output ports, for example, output port 114A is operable to output multiple voltages depending on the configuration or type of the power cable and is thus referred to as a variable voltage output port. As an example, the output port 114A can operate as a standard 5 V compliant USB port when a standard USB cable is connected. However, when a special cable is connected, the operation of the output port 114A is modified to operate at a higher voltage (e.g., 19.5 V), which is suitable for charging a portable computer. Thus, the output port 114A is variable depending on the cable that is connected, providing functionality not available using conventional designs.

Others of the plurality of output connections, for example, output ports 114B and 114C do not modify their operation in response to the cable that is connected. In one implementation, output ports 114B and 114C are standard 5 V USB ports that can be used to charge mobile phones, tablets, or the like. Thus, standard USB cables can be plugged into ports 114B and 114C and will operate as a standard USB cable, for example, at 5 V output.

It should be noted that in some embodiments, the output ports 114A, 114B/114C are modified USB ports and standard USB ports, respectively. However, this is not required by the present invention and other connector designs can be utilized including standardized and proprietary connector designs, including plugs, receptacles, and terminal blocks. One of ordinary skill in the art would recognize many variations, modifications, and alternatives.

Referring to FIG. 1A, the power cable 120 has a modified USB connector 122 that includes a key 124 that extends a predetermined distance toward the end of the modified USB connector 122. As illustrated in FIG. 1A, the key 124 is disposed on the exterior surface of the power cable, although other keying arrangements are included within the scope of the present invention. Port 114A on the power unit includes a matched opening 116 to receive the key 124. The key 124 prevents the power cable 120 from being inserted into a standard USB connector as illustrated in FIG. 1C, in which insertion of the modified USB connector 122 into port 114B is prevented by the key 124 butting against the housing 112. It should be noted that ports 114B and 114C lack opening 116 adjacent to their port, thereby preventing power cable 120 from being inserted into either of ports 114B and 114C. As illustrated in FIG. 1B, once the power cable 120 is inserted into port 114A, the key (not shown) is positioned in the matched opening, the edge of which is illustrated by line 130

It should be noted that in FIGS. 1A-1C, only a single variable output port is illustrated, but embodiments of the present invention are not limited to a single variable output port. In other embodiments, multiple variable output ports are provided, each including a key, which can be identical or different depending on the application. Thus, in one implementation, a first power cable having a first key could be connected to a first variable output port and utilized to charge a laptop computer. A second power cable having a second key could be connected to a second variable output port and utilized to charge a different voltage laptop computer or another electronic device that is charged at a different voltage than a laptop computer. Although some embodiments of the present invention work in conjunction with keyed output cables, this is not required by the present invention. Rather, some embodiments provide a variable voltage output at one or more of the output ports without the use of a key and keyhole. In some implementations, the key on the output cable prevent misidentification of parts by a user and does not provide an electrical function.

Referring to FIG. 1A, the power unit includes port 114A, which is a variable voltage port and ports 114B and 114C, which are standard USB ports. Thus, in comparison with multiple output USB devices, embodiments of the present invention provide different voltage outputs from different ports. Although multiple ports 114A, 114B, and 114C are illustrated in FIG. 1A, it should be noted that a single variable output port could be provided in some implementations, with the voltage of the port varying depending on the power cable that is utilized in conjunction with the power unit. Thus, a single port embodiment of the power supply is included with the scope of the present invention providing a power adapter that can output multiple voltage levels depending on configuration.

FIG. 1D is a perspective view of a single output power unit according to an embodiment of the present invention. As illustrated in FIG. 1D, the power unit 150 includes a single variable output power port 151. Similar to port 114A, port 151 is able to provide two or more output voltages as a function of the power cable that is connected to the port. In an embodiment, port 151 is able to output 5V when a standard USB cable is connected and 19.5V when a special (e.g., high voltage) power cable is connected. Although 19.5V is utilized to represent a conventional laptop computer charging voltage, the present invention is not limited to this particular voltage and other voltages including 12V, 14V, 16.5V, 18V, 20V, and 21V, as well as voltage ranges around these values, for example, 19.0V-19.9V as a range around 19.5V are included within the scope of the present invention. In other embodiments, the port is able to output additional voltages or a range of voltages as described herein. In the implementation illustrated in FIG. 1D, no matched opening operable to receive a key is provided. Thus, some embodiments of the present invention do not require the keying function described herein.

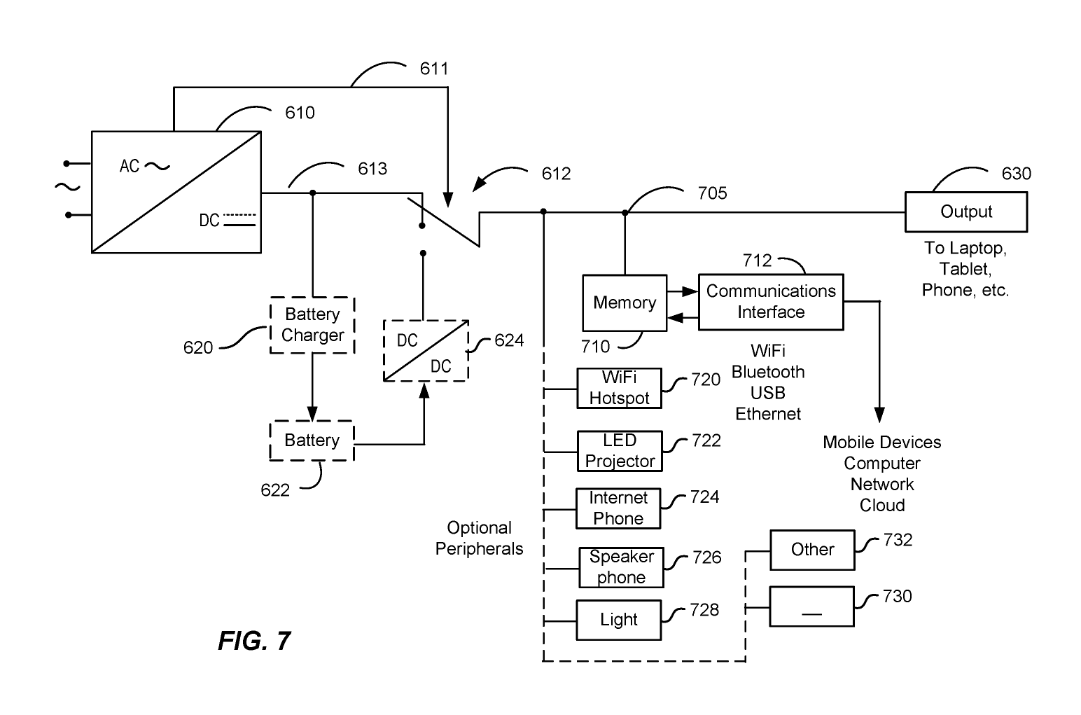

Referring once again to FIG. 1A, the variable output power supply 100 includes an access port 140 that provides input/output access to one or more accessories (not shown, but discussed in relation to FIG. 7) that are disposed in the housing. As an example, if a memory is disposed in the housing, access port 140 can provide read/write access to the memory. In some embodiments, wireless communications between the one or more accessories and corresponding external devices obviate the need for the access port 140 to provide input/output access to the one or more accessories.

Although access port 140 is illustrated as a USB port in FIG. 1A, this is not required by the present invention and other form factors for the access port 140 are included within the scope of the present invention as appropriate to the particular application. For example, a memory may be accessed through an appropriate memory chip standard connector, including mini SD, microSD, or the like. One of ordinary skill in the art would recognize many variations, modifications, and alternatives.

FIG. 2 is a drawing illustrating a keyed power cable according to an embodiment of the present invention. As illustrated in FIG. 2, the power cable 120 includes a modified USB connector 122 on the end of the power cable that plugs into the power unit 110 and a standardized laptop computer connector 220 on the other end of the power cable. The power cable is suitable for charging high power devices such as laptop computers. Although the power cable shares some similarities with standard USB cables, the key 124 present on the modified USB connector 122 prevents the power cable 120 from being inserted into a standard USB connector as illustrated in FIG. 1C. As discussed above, the key 124 is not required by the present invention.

Embodiments of the present invention are compliant with a variety of USB standards including USB 2.0 and USB 3.0, USB 3.1, or the like. As described herein, the functionality of the system does not rely on USB compliant cables, but USB cables are illustrated for the purpose of explaining operation of the system. One of ordinary skill in the art would recognize many variations, modifications, and alternatives.

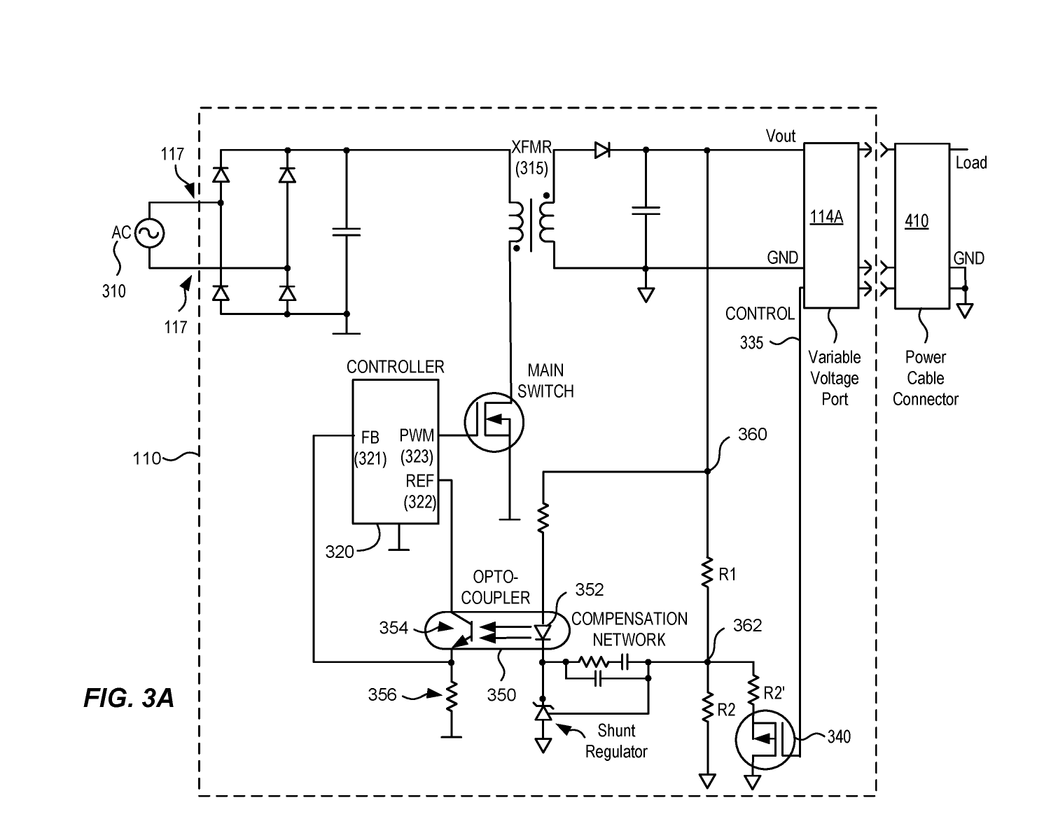

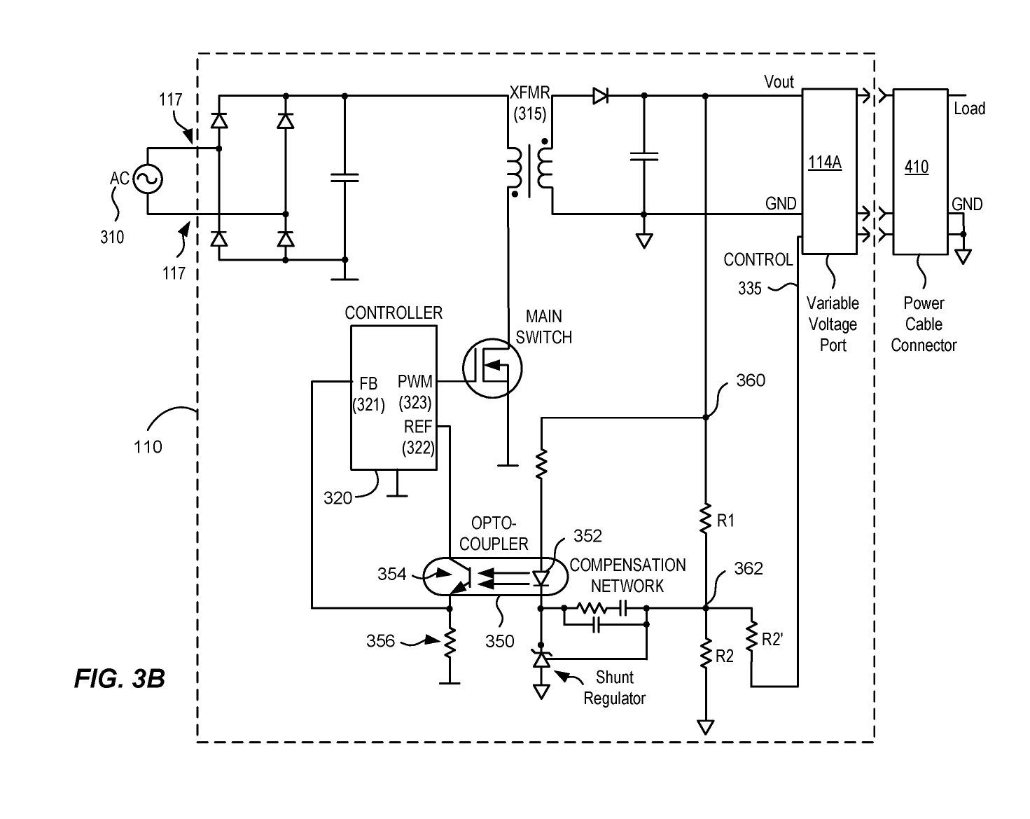

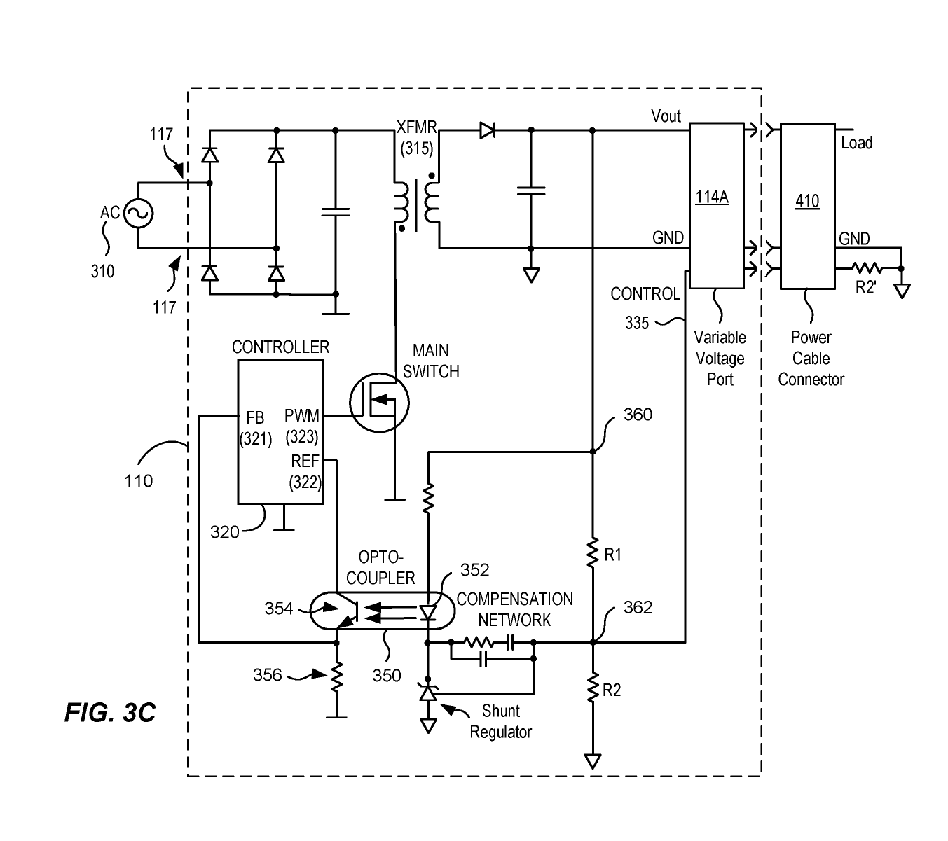

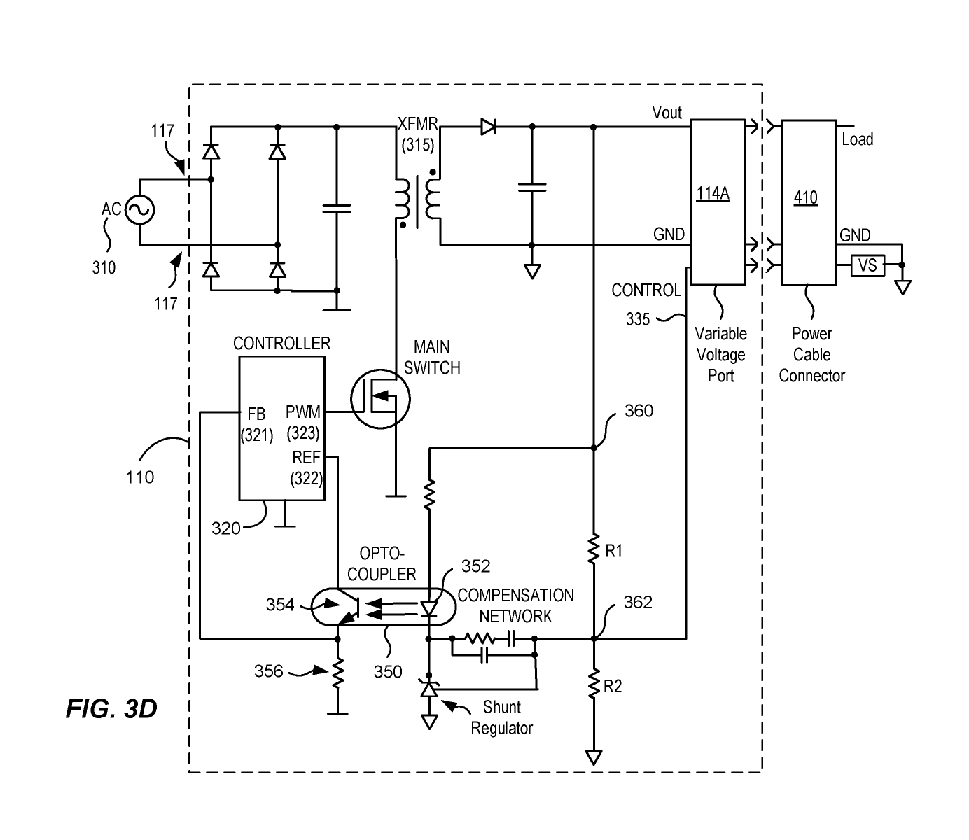

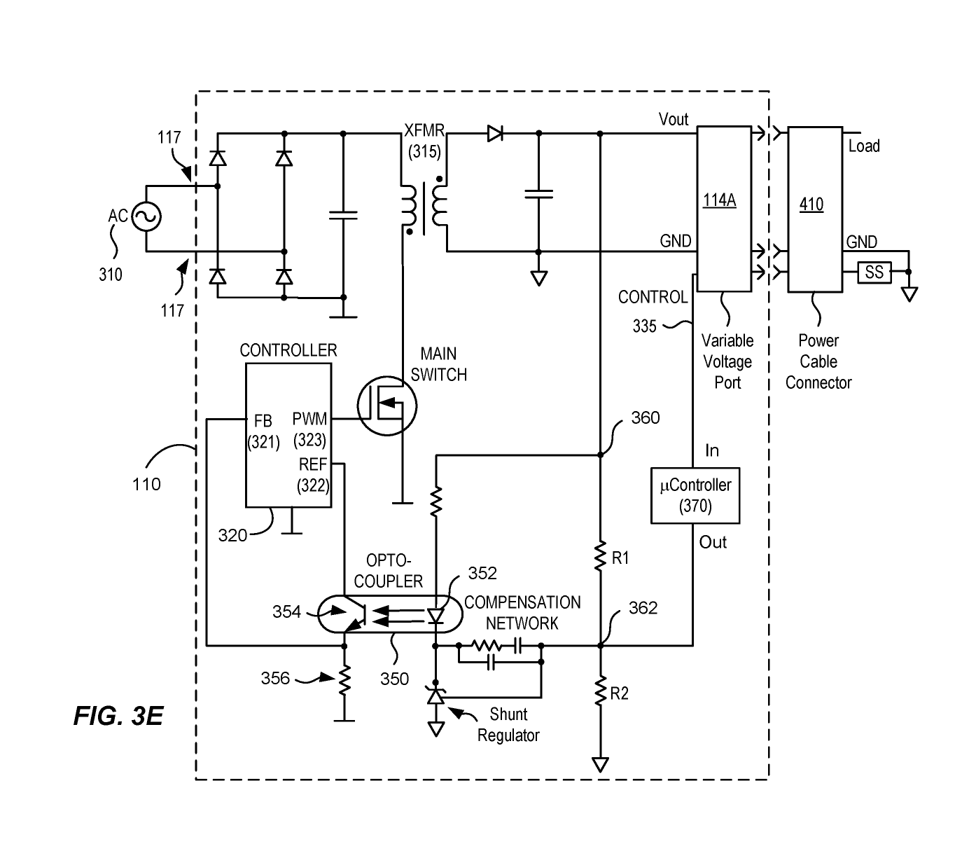

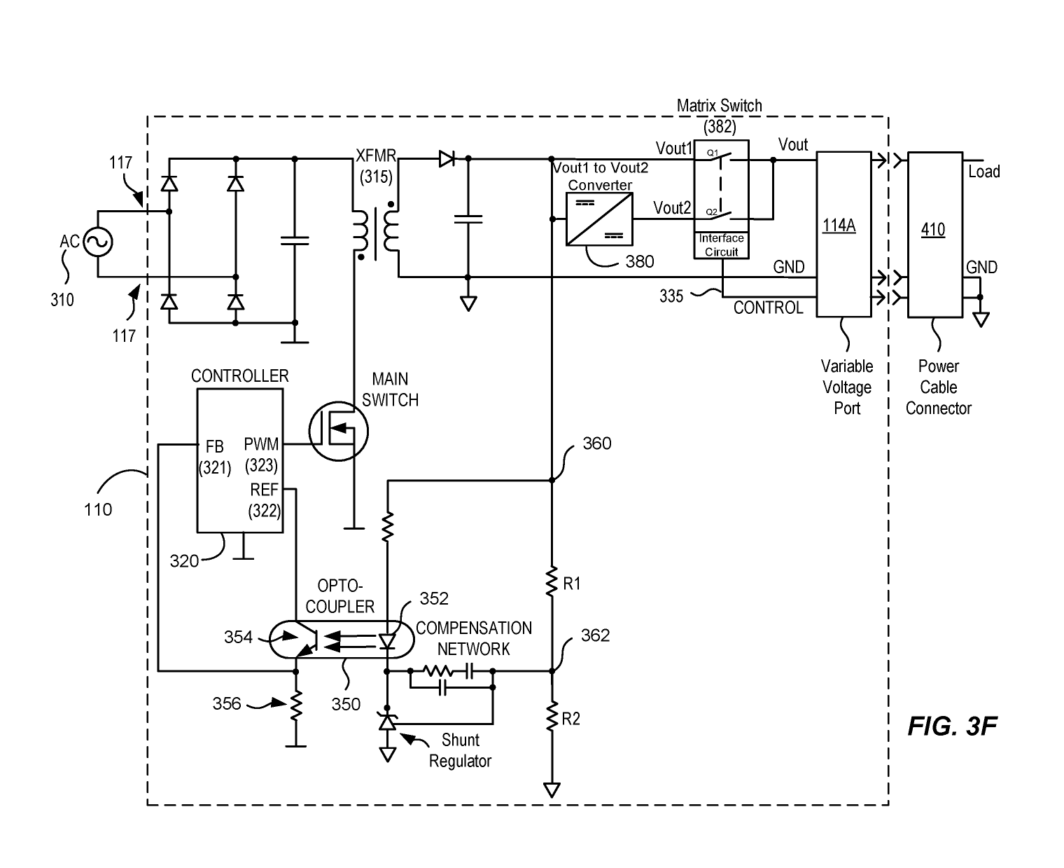

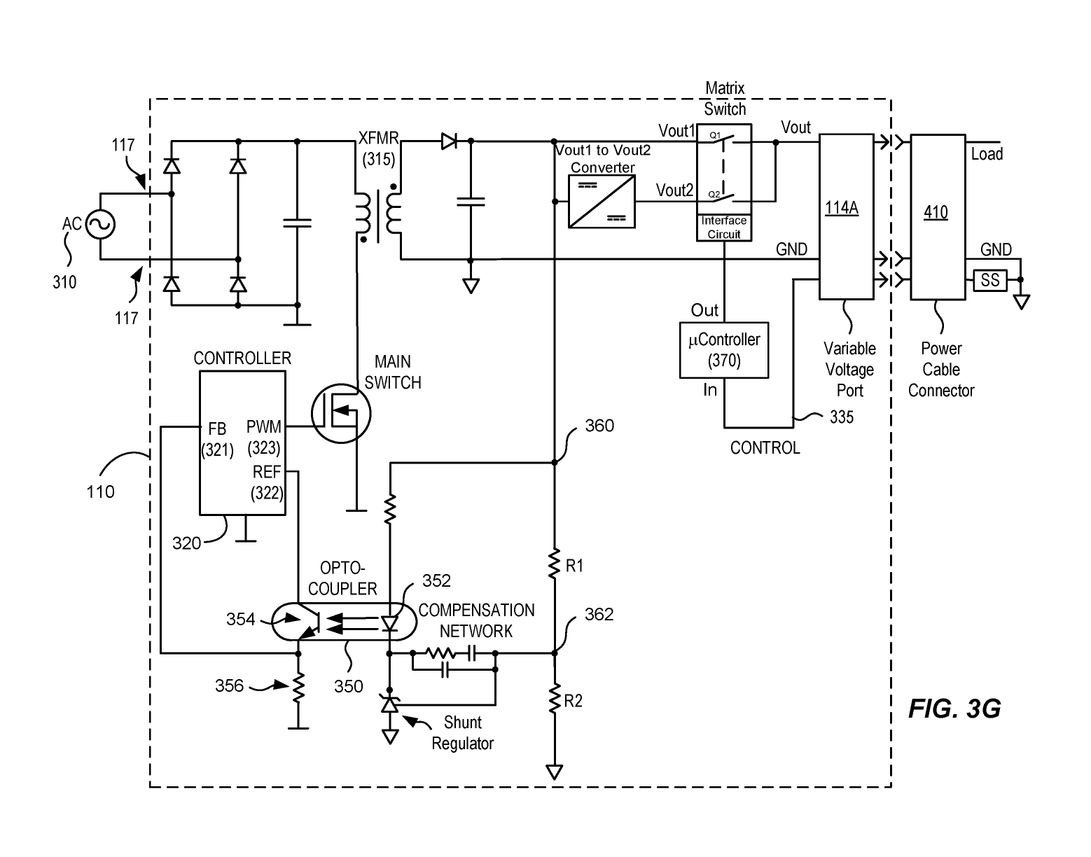

FIG. 3A is a simplified schematic diagram of the power unit of the variable output power supply according to an embodiment of the present invention. The power unit (illustrated by reference number 110 in FIG. 1A) includes an electrical connection to an external power supply 310. In the embodiment illustrated in FIG. 1A, a set of extendable prongs 117 are utilized to connect the power unit to an AC voltage source such as a wall socket. In FIG. 1A, the set of prongs are illustrated in the collapsed position and in FIG. 1B, the set of prongs are illustrated in the extended position. The power unit includes a transformer 315 that connects two halves of the power unit. A controller 320 includes a feedback input 321, a reference output 322, and a pulse width modulation (PWM) output 323.

The power unit includes variable voltage port 114A. Electrical connections in the variable voltage output port 114A include Vout, ground, and a control connector. When a power cable having a first type of connector (e.g., a standard connector) is connected to the variable voltage output port 114A, the control line 335 is either floating or at a predetermined voltage and the control FET 340 is in the off state. An example of operation in this state would be when a standard USB connector is inserted into the variable voltage output port. In this case, the control line is floating, the control FET 340 is off, no current flows through R2′ and the voltage Vout and the current through the photodiode 352 in optocoupler 350 is determined by the values of resistors R1 and R2. In some implementations, the current transfer ratio of the optocoupler is unity such that if 1 mA is flowing through the photodiode 352, then 1 mA is generated at the phototransistor 354. The current through the phototransistor 354 and the feedback resistor 356 connected to the emitter of the phototransistor 354 determine the voltage that is used as an input to the feedback input 321 of the controller 320. A precision shunt regulator, which is connected to the compensation network controls voltage on the cathode of the photodiode 352.

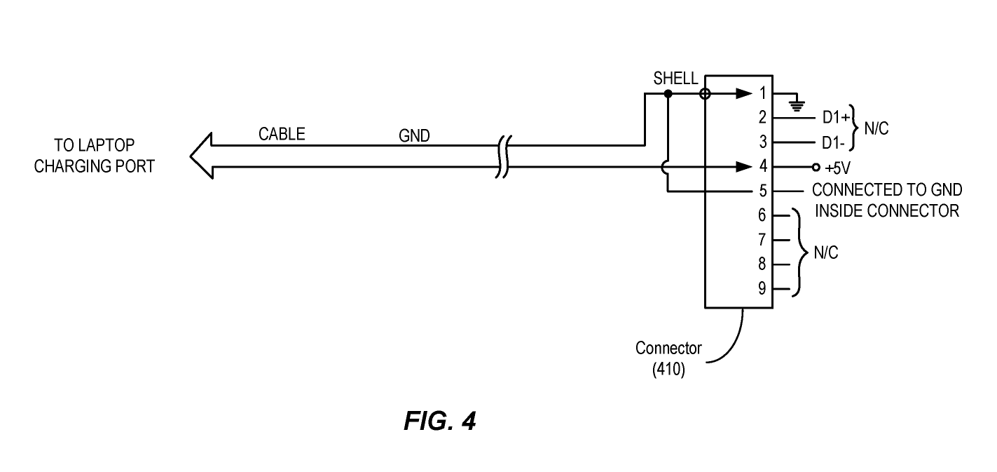

When a power cable with a second connector (e.g., a modified connector) is inserted into the variable voltage output port 114A, then the control line 335 is grounded as a result of the design of the connector (discussed in additional detail in relation to FIG. 4). The grounding of the control line 335 results in the control FET 340 turning on and connecting R2′ to ground. In this configuration, the voltage at node 362 is a function of R2 and R2′ connected in parallel. This modification in voltage resulting from the connection of R2′ in parallel with R2 produces a change in the voltage applied to the cathode of the photodiode 352 and the current in phototransistor 354. The resulting change in the current through and voltage across the feedback resistor 356 results in the controller detecting a change in the voltage at the feedback input 321. The controller 320 then adjusts the PWM output 323 accordingly to modify the output voltage at Vout. Thus, the power unit is able to detect connection of a power cable used for high power operation and modify the voltage of the variable power output port 114A in response to the connection of the special power cable as described throughout the present specification.

In FIG. 3A, the controller 320 is an element of control circuitry, including control line 335, that is connected through control line 335 to the output port that includes the variable output capability. In some sense, the controller 320 and other elements of the control circuitry, which can include microcontroller 370 as illustrated in FIG. 3E, are connected to the variable voltage output port through control line 335. Direct connection is not required since the various components of the control circuitry, including control line 335, resistor R1, resistor R2, resistor R2′, transistor 340, the compensation network, the shunt regulator, the opto-coupler 350, and the main switch, serve specific functions in enabling the variable voltage port to vary the output voltage Vout in response to the connection of the power cable 410 to the variable voltage port 114A.

Although the embodiment illustrated in FIG. 3A utilizes grounding of the control line 335 as a result of grounding of one of the pins inside the power cable, other designs that provide an indication that a special, high power cable has been connected are included within the scope of the present invention. As an example, another implementation utilizes a matrix switch design in which each voltage rail is routed to the output via a switch. When the special power cable is connected, one of the switches is turned on, thereby changing the output voltage. In another alternative implementation, a microcontroller is used that reads the configuration of the cable and changes the output voltage accordingly (e.g., via a digital to analog converter). This alternative implementation enables different voltages to be provided in conjunction with different power cables.

Referring to FIGS. 1A, 1B, and 3A, the variable output power supply includes a power unit 110 that comprises a set of prongs 117 operable to plug into a power outlet 310. The power unit includes a housing 112 that includes a plurality of output ports 114A, 114B, and 114C. The power unit also includes a keyhole 116 disposed in the housing adjacent one of the plurality of output ports (variable output port 114A). The power unit also includes control circuitry disposed in the housing, illustrated in FIG. 3A, and connected to the one of the plurality of output ports. A power cable is used in conjunction with the power unit and includes a key 124 that is operable to be inserted into the keyhole. When the power cable is inserted into the variable output port 114A, the control circuitry is operable to modify operation of the at least the variable output port 114A, for example, increasing the output voltage of the variable output port. In some embodiments, the modification in operation is referred to as being performed in response to insertion of the power cable in the variable output port although other conditions can be applied prior to modification. In some embodiments, insertion is sufficient to provide configuration information on the power cable that is used by the control circuitry to modify the operation.

FIG. 3B is a simplified schematic diagram of the power unit of the variable output power supply according to a particular embodiment of the present invention. As illustrated in FIG. 3B, resistor R2′ is connected to the control line 335. In some implementations, the resistor R2′ can be integrated into the connector of the variable voltage port 114A. When the power cable connector 410 is connected to the variable voltage port 114A, the grounding of the pin to which the control line is thus connected will ground the control line 335, placing R2′ in parallel with R2 and, thereby, changing the voltage at node 362 as discussed in relation to FIG. 3A.

It should be noted that although some embodiments are described in terms of a dual voltage output (i.e., 5V or 19.5V), the present invention is not limited to these voltages. In some embodiments, three or more voltages are provided as appropriate to the particular voltage suitable for device charging. In other embodiments, an output voltage that is continuously variable or variable in increments is provided as described in relation to FIG. 3D, in which the voltage source can be a continuously variable source or a source that varies incrementally, for example, as different resistors are utilized in different output cables.

FIG. 3C is a simplified schematic diagram of a single output implementation of the power unit of the variable output power supply according to an embodiment of the present invention. In the embodiment illustrated in FIG. 3C, resistor R2′ has been integrated into the power cable connector 410. When the power cable connector 410 is connected to the variable voltage port 114A, the control line 335 is connected to ground through resistor R2′, placing R2′ in parallel with R2 and, thereby, changing the voltage at node 362 as discussed in relation to FIG. 3A.

FIG. 3D is a simplified schematic diagram of another single output implementation of the power unit of the variable output power supply according to an embodiment of the present invention. In the embodiment illustrated in FIG. 3D, a voltage source (VS) is connected between a pin of the power cable connector 410 and ground. The connection of the power cable connector 410 to the variable voltage port 114A results in the voltage source VS being connected between node 362 and ground, which modifies the voltage at node 362 and, as a result, the voltage at node 360 as discussed in relation to FIG. 3A. In one implementation, the voltage source is a voltage divider between the bus voltage and the ground. Accordingly, the voltage source VS provides a voltage level to the control line 335 that is then present at node 362. Thus, some embodiments include a voltage source inside the power cable that provides a predetermined voltage to the control line of the power supply. As an example, the resistors selected for the voltage source can result in a voltage at node 362 that will result in two different voltages being produced by the variable voltage port 114A.

In one particular implementation, multiple output cables are provided, each with a unique voltage source VS. In this particular implementation, an arbitrary number of voltages can be provided, for example, a 5 V output for a 5 V cable, a 12 V output for a 12 V cable, a 19.5 V output for a 19.5 volt cable, and the like. In each cable, the appropriate voltage source will be provided to produce the desired voltage at the output.

FIG. 3E is a simplified schematic diagram of yet another single output implementation of the power unit of the variable output power supply according to an embodiment of the present invention. In the embodiment illustrated in FIG. 3E, a signal source (SS) is connected between a pin of the power cable connector 410 and ground. The connection of the power cable connector 410 to the variable voltage port 114A results in the signal source SS being connected between the input of microcontroller 370 and ground. The signal source provides a voltage or current to control line 335 that is received as an input to the microcontroller (μController) 370. The microcontroller receives the input voltage/current and outputs a voltage that is received at node 362.

The microcontroller can map the inputs (or a range of inputs) to a set of outputs, removing, in the case of a voltage source connected to control line 335, the proportionality between the input voltage on control line 335 and the voltage at node 362. For example, a 1 kΩ resistor in the SS would map to a 5 V Vout, a 2 kΩ resistor in the SS would map to a 12 V Vout, and a 3 kΩ resistor in the SS would map to a 19.5 V Vout, removing the linearity between resistor value and output voltage Vout as the microcontroller distinguishes between different resistors, as well as providing predetermined output voltages when resistors vary from the desired value (e.g., a range of resistors having values from 900Ω to 1.1 kΩ could be understood as a 1 kΩ resistor). Benefits provided by the system illustrated in FIG. 3E include the ability to use commonly available resistors (with limited accuracy) since the resistor value does not directly determine the voltage at node 362, which is determined by the output of the microcontroller 370. Thus, embodiments illustrated in FIG. 3E utilize the microcontroller 370 to provide a single output at node 362 that absorbs variance in the value of the input voltage received by the microcontroller (e.g., the value of a resistor in the voltage source).

FIG. 3F is a simplified schematic diagram of a dual output implementation of the power unit of the variable output power supply according to an embodiment of the present invention. As illustrated in FIG. 3F, a voltage converter 380 is operable to convert voltages from a first voltage (e.g., Vout1) to a second voltage (e.g., Vout2). A first input of matrix switch 382 is connected to node 360. The input to the voltage converter is connected to node 360 and the output of the voltage converter is connected to a second input of matrix switch 382. The matrix switch 382 includes an interface circuit connected to the control line of the variable voltage port 114A.

Initially, the matrix switch 382 is operated in a state that produces an output voltage Vout equal to either Vout1 or Vout2, typically Vout1. When the power cable connector 410 is connected to the variable voltage port 114A, the control line is connected to ground, thereby grounding the input to the interface circuit. The grounding of the interface circuit causes the matrix switch to switch the output at Vout from one voltage to another (e.g., Vout1 to Vout2), or vice versa depending on the particular implementation. Thus, in a manner similar to other embodiments, the power unit senses the configuration of the power cable and adjusts the output voltage accordingly. In this embodiment, the output voltage is switched between two voltage outputs in response to the connection and disconnection of the power cable connector to the variable voltage port.

FIG. 3G is a simplified schematic diagram of another dual output implementation of the power unit of the variable output power supply according to an embodiment of the present invention. In the embodiment illustrated in FIG. 3G, a signal source (SS) is connected between a pin of the power cable connector 410 and ground. The connection of the power cable connector 410 to the variable voltage port 114A results in the signal source SS being connected between the input of microcontroller 370 and ground. The control line 335 provides an input to the microcontroller 370, which provides, as an output, an input to the interface circuit of the matrix switch. As described in relation to FIG. 3F, the interface circuit causes the matrix switch to switch the output at Vout from one voltage to another (e.g., Vout1 to Vout2), or vice versa depending on the particular implementation. The combination of the signal source and the microcontroller provides an alternative to the grounded control line illustrated in FIG. 3F in a manner similar to the combination of the signal source and microcontroller illustrated in FIG. 3E provided an alternative to the voltage source illustrated in FIG. 3D. One of ordinary skill in the art would recognize many variations, modifications, and alternatives.

FIG. 4 is a schematic diagram illustrating a pin configuration for a power cable according to an embodiment of the present invention. As illustrated in FIG. 4, the power cable includes a number of pins 1-9 disposed in a connector 410. In an embodiment, the connector 410 is a USB compliant connector that provides additional functionality. In an embodiment, Pin 1 of the connector is grounded to the shell of the connector. The USB communication interface (D1+ and D1−) is provided on Pins 2 and 3 and 5V is output on Pin 4, which are unchanged from a standard USB cable.

Pin 5 is connected to ground, for example, by grounding (e.g. inside the connector) to the shell to which Pin 1 is grounded. In operation, when the connector is connected to the variable power output port of the power unit, the grounding of Pin 5 is sensed by the power unit 110, which modifies the output voltages on Pin 4 in response to the connection of the illustrated power cable. In this embodiment, no change is made to Pins 6-9. The end of the power cable opposing connector 410 provides a computer connector that is suitable for charging of different computers, including laptop computers and other mobile or battery powered computers. Since different computers utilize different power connectors, the charging connection will be modified depending on the particular application. One of ordinary skill in the art would recognize many variations, modifications, and alternatives.

As described in relation to FIG. 3A, the grounding of Pin 5 modifies the voltage at a node of the voltage divider, enabling a controller in the power unit to increase the output voltage (e.g., 19.5 V) that is provided to Pin 4. Although Pin 5 is utilized in this exemplary embodiment to provide information to the power unit related to the voltage rating of the power cable, other suitable pins can be utilized according to embodiments of the present invention.

Thus, using embodiments of the present invention, the power unit is able to modify the output voltage (thus, the reference to a variable output power supply) depending on the type of power cable that is connected to the power unit. In the embodiment illustrated in FIG. 4, when a standard USB (e.g., USB 3.0) cable is connected, then Pin 4 outputs +5 V. On the other hand, when the power cable with Pin 5 grounded is connected to the power unit, the output of Pin 4 is changed to +19.5 V, which is compatible with laptop computer charging. As will be evident to one of skill in the art, the particular voltages (e.g., +5 V and +19.5 V) are utilized merely by way of example and the present invention is not limited to these particular voltage values. In other embodiments, the performance of the variable output power supply is measured in terms of power (wattage).

Although some embodiments of the present invention are discussed in relation to laptop computer charging, embodiments of the present invention are not limited to this particular application and other specialized power cables can be implemented for various non-standard charging applications. As an example, a power cable for a tablet, camera, PDA, navigation device, gaming consoles, camcorders, headphones, or the like could have a pin other than Pin 5 grounded, indicating operation at the appropriate predetermined charging voltage. In response to one of these power cables being plugged into the power unit, the power unit would modify the output voltage to the appropriate voltage for the particular device. One of ordinary skill in the art would recognize many variations, modifications, and alternatives.

Thus, the power cable in this embodiment is configured such that insertion into the output port of the power unit results in modification of the operating state of the output port. In some implementations, the connector 410 is a modified USB connector that includes a key that prevents the power cable from being inserted into a standard USB port as illustrated in FIG. 1C. Although the power cable illustrated in FIG. 4 shares some similarities with conventional USB cables, the power cable is able to operate at higher voltages than conventional USB cables, enabling the power cable to provide a laptop computer charging functionality.

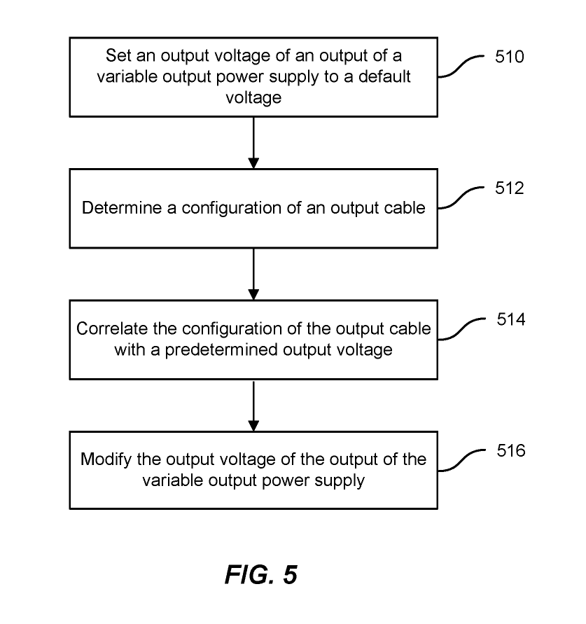

FIG. 5 is a simplified flowchart illustrating a method of operating the variable output power supply according to an embodiment of the present invention. The method includes setting an output voltage of an output of the variable output power supply to a default voltage (510). In an embodiment, the default voltage is 5V, which is the voltage associated with an output cable that is compliant with the USB standard. Thus, conventional cables, including USB-compliant cables can be utilized with the variable output power supply described herein.

The method also includes determining a configuration of an output cable (512) and correlating the configuration of the output cable with a predetermined output voltage (e.g., 19.5 V) (514). Determining the configuration can be done by measuring a voltage or current associated with a pin of the output cable, which can be a power cable for a laptop computer or other suitable electronic device. When the output cable is connected to an output port of the variable output power supply, the pins of the output cable are connected to the pins of the output port, enabling voltages and currents present on the pins of the output cable to be measured, including a determination that one of the pins of the output cable is grounded. Based on the configuration of the output cable, the correlation between the configuration and the desired output voltage of the power supply can be established.

As an example, the grounding of one of the pins of the output cable as illustrated in FIG. 3A results in resistor R2′ being placed in parallel with resistor R2, thereby changing the voltage at node 362. In this case, the configuration of the output cable (i.e., grounding of the pin connected to control line 335) is correlated with an increase in Vout to the predetermined voltage. In some cases, for example, as illustrated in FIG. 3C, the value of resistor R2′ in the output cable connector results in a direct correlation between the configuration of the output cable and the predetermined output voltage, whereas in other embodiments, as described below in relation to FIG. 3E, the correlation is not direct, but can be mapped in a non-linear or other manner. As another example, in FIG. 3E, the configuration of the output cable results in the connection of the signal source SS to the control line 335. The microcontroller determines that for this configuration of the output cable, the presence of and value associated with the signal source indicates the correlation between the configuration of the output cable (i.e., value of the signal source signal) and the voltage Vout that is provided by the variable voltage port 114A. As described in relation to FIG. 3E, different signal source signals (e.g., the current associated with a 1 kΩ resistor vs. a 2 kΩ resistor) are correlated with different output voltage (e.g., Vout=5 V vs. Vout=19.5 V). Thus, in this example, different configurations of the output cable are correlated with different output voltages.

The method further includes modifying (e.g., increasing) the output voltage of the output of the variable output power supply (516). As examples, the output voltage can be increased from 5 V to 19.5 V. In some embodiments, the method includes detecting connection of the power cable to the output of the variable output power supply.

It should be appreciated that the specific steps illustrated in FIG. 5 provide a particular method of operating a variable output power supply according to an embodiment of the present invention. Other sequences of steps may also be performed according to alternative embodiments. For example, alternative embodiments of the present invention may perform the steps outlined above in a different order. Moreover, the individual steps illustrated in FIG. 5 may include multiple sub-steps that may be performed in various sequences as appropriate to the individual step. Furthermore, additional steps may be added or removed depending on the particular applications. One of ordinary skill in the art would recognize many variations, modifications, and alternatives.

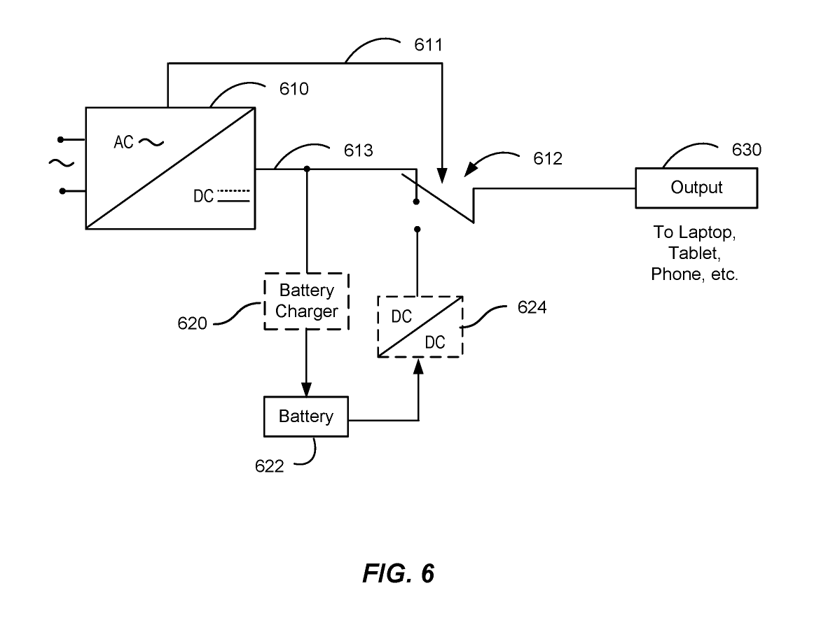

FIG. 6 is a simplified schematic diagram illustrating a power supply with an integrated battery according to an embodiment of the present invention. As illustrated in FIG. 6, an AC-DC converter 610 is connected to a switch 612. The AC-DC converter 610 receives power from an AC connection, for example, a wall socket. In an embodiment, the AC-DC converter is a component of the power unit of the variable output power supply as illustrated in FIG. 1A. The AC-DC converter is connected to an optional battery charger 620 and a battery 622. An optional DC-DC converter 624 is connected to the battery. The components illustrated in FIG. 6 can be included within the housing of the power unit illustrated in FIG. 1A.

When the input is connected to an AC source, the control line 611 will switch the switch 612 to connect the output 613 of the AC/DC converter 610 to the output port 630, which can be connected to a variety of electronic devices, including, without limitation, a laptop computer, a tablet, a phone, or the like. During this state of operation, the AC-DC converter provides power to charge and/or operate the electronic device connected to the output port 630.

As described herein, the power unit of a variable output power supply is provided with additional functionality by the addition of the battery 622, the optional battery charger 620, and the optional DC-DC converter 624. This added functionality enables the battery 622 to be used to charge and/or operate the electronic devices using the output port 630 when external AC power is not available. Accordingly, embodiments of the present invention provide the variable output characteristics described herein, supplemented by a power source when external power is not available. The battery 622 and optional battery charger 620 enable the electronic devices to be charged at various power levels as described herein, for example, as a function of the power cable that is connected to the output port.

As an example, when the variable output power supply is connected to an external power source and a laptop is connected to the output port, the variable output power supply detects the connection to the laptop and modifies the output voltage to a voltage appropriate for laptop operation/charging. If the power supply is then disconnected from the external power source, switch 612 can switch to provide power from the battery to the output port. Accordingly, continuous operation/charging of the laptop can be accomplished using embodiments of the present invention, providing functions associated with uninterruptible power supplies. Thus, regardless of whether external power is available, electronic devices can be powered and charged. As will be evident to one of skill in the art, this discussion is applicable to other electronic devices in addition to a laptop. One of ordinary skill in the art would recognize many variations, modifications, and alternatives.

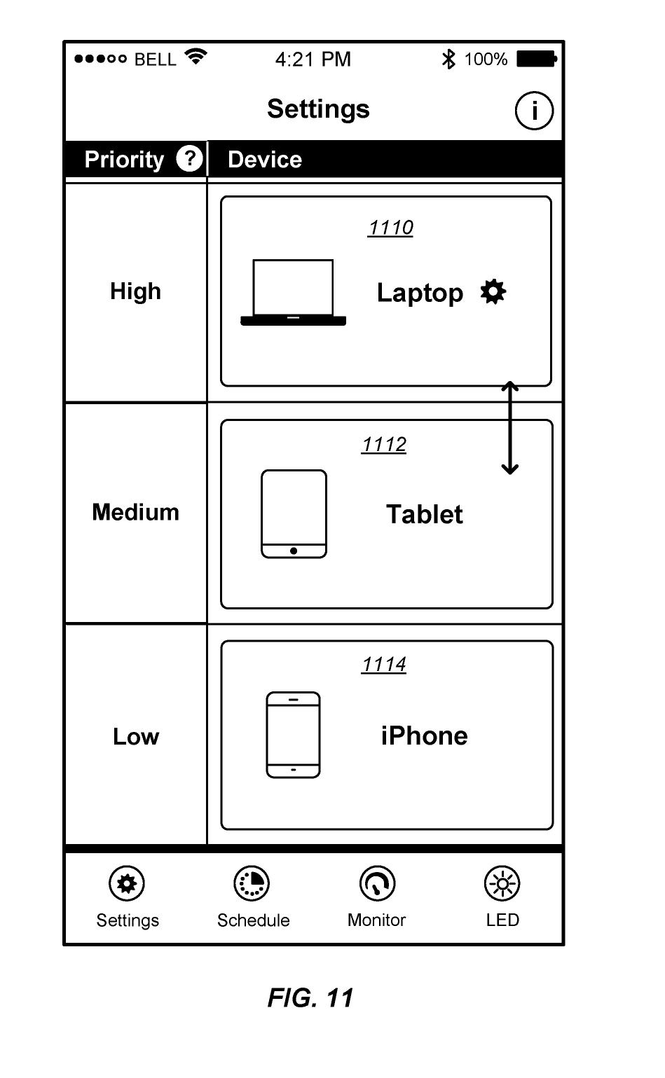

Referring to FIG. 6, when the power unit is connected to external power, the switch connects the output of the AC-DC adapter to the output port. Concurrently, extra power available from the AC-DC adapter can be used to charge battery 622 until the battery is fully charged. Thus, both powering/charging of electronic devices connected to the output port and charging of the battery contained in the housing of the power unit can be performed concurrently. When external power is not connected, the switch connects to the DC-DC converter to power the output port using the battery. In some implementations, control of the power unit can be provided through a user interface such as those illustrated in relation to FIG. 11 and other drawings. As an example, the battery 622 can be controlled as one of the devices illustrated in FIG. 11. In these implementations, the battery would appear as one of the devices and a priority for the charging of the battery could be set in a manner similar to the priorities for the other illustrated electronic devices.

In some embodiments when external power is not available and the battery 622 is being used to provide power to the output port, the number of electronic devices connected to the output port may exceed the capacity of the battery to provide full power to all of the electronic devices. In this case, priority of power provisioning can be implemented as described herein in the context of external power. Priorities for different devices can be set and modified in view of the power available from the battery. As an example, if the user connects a tablet, a phone, and a laptop to the output port, the battery could be drained quickly as a result of the high power demand associated with the laptop. Accordingly, default priorities could be set to charge/power the phone/tablet first and then to charge/power the laptop. A user can adjust these default settings as described herein.

FIG. 7 is a simplified schematic diagram illustrating a power supply with one or more integrated accessories according to an embodiment of the present invention. The one or more integrated accessories illustrated in FIG. 7 can be disposed in the housing of the variable output power supply and accessed through access port 140 as discussed in relation to FIG. 1A. In some embodiments, wireless communications capability provided by the variable output power supply are utilized to provide input/output access to the one or more accessories disposed in the housing of the power supply. In some embodiments, the one or more accessories are mounted in the housing, with a portion of the accessory protruding from the housing to provide for access by a user. One of ordinary skill in the art would recognize many variations, modifications, and alternatives.

Referring to FIG. 7, the battery functionality discussed in relation to FIG. 6 is provided as an optional feature in the embodiment illustrated in FIG. 7. Although this battery functionality is illustrated in FIG. 7, it should be noted that one or more of the functions illustrated in FIG. 7 can be deleted, enabling the power supply to provide one or more, including all, of the functionality illustrated in FIG. 7. In embodiments in which the battery is not used in the system discussed in relation to FIG. 7, the switch 612 can be eliminated and the output 613 can be connected to node 705. The one or more integrated accessories can be included within the housing of the power unit illustrated in FIG. 1A.

A memory 710 is provided in communication with a communications interface 712, which can be either wired or wireless. As an example, the communications interface can utilize protocols including WiFi, Bluetooth, USB, Ethernet, or the like, providing communications with electronic devices including mobile devices such as smart phones, computer, computer networks, cloud services, or the like.

Referring to FIG. 7, a memory 710 is included in the housing of the power unit and coupled to a communications interface 712, which can be either wireless (e.g., WiFi, Bluetooth, or the like) or wired (e.g., USB, Ethernet, or the like). The memory, which can be a flash memory or other suitable memory, can be used to store data that is accessible to electronic devices through the communications interface. Thus, embodiments provide access to an external memory accessible from a mobile device.

The memory 710 can act as a wireless hard drive to which data can be uploaded and from which data can be downloaded. When the AC/DC converter is connected to external power, the external power can be used to provide power to the memory and communications interface. When the AC/DC converter is not connected to external power, the battery can be used to provide power to the memory and communications interface. Data stored in the memory can be accessed by mobile devices and other electronic devices and made accessible to networks and cloud storage. Additionally, data stored on computer networks or in the cloud can be downloaded and stored on the memory.

Thus, since the embodiment illustrated in FIG. 7 provides the functionality of a memory combined with a power supply, a user does not need to carry separate memory, which is typically done using conventional memory. The ability to power the memory and communications interface using the battery provides functionality not available using conventional USB drives, which are only accessible when plugged into a USB slot connected to a computer. In contrast with these conventional memories, embodiments of the present invention can be accessed, for example, using a smart phone to move data from a network to the memory 710, from the memory to the smart phone, and the like. When the power unit is connected to an electronic device, for example, using the power cable, then the memory can be accessible to the electronic device through the power cable. Also, the memory can be accessible using wireless protocols. One of ordinary skill in the art would recognize many variations, modifications, and alternatives.

FIG. 7 illustrates several additional optional peripherals that can be provided in conjunction with the power supply. These include an LED/laser projector, a speakerphone, an internet-capable phone, various lights including night lights, flash lights, and the like. The internet-capable phone could be implemented in conjunction with one of the illustrated USB ports or through an Ethernet port on the housing of the power unit. A handset would connect to the internet-capable phone using either these physical connections or wirelessly using the communications interface. In some embodiments, a pass-through AC socket is provided on the power unit, enabling other devices to be connected to power.

Embodiments of the present invention enable location services that can prevent loss of the power supply. These location services become important as functionality is added to the power supply through the accessories/peripherals described herein, thereby increasing its value. The communications interface, which can include operation using the Bluetooth standard, can establish a connection to a mobile device, such as a user's smart phone. The connection will be maintained while the mobile device is in the vicinity of the power supply, for example, within 30 feet.

If the connection between the power supply and the mobile device is terminated, for example, if the user leaves the vicinity of the power supply while it is plugged into an external power source, a notification can be provided to the mobile device indicating that the connection has been terminated. In this manner, the user is alerted to forgetting the power supply when they move to a new area, thereby preventing loss. Although this functionality of loss prevention has been described in relation to the power supply being connected to external power, the implementations utilizing a battery can provide this loss prevention functionality when not plugged into external power.

According to an embodiment of the present invention a method of preventing loss of a power supply is provided. The method includes establishing a wireless connection between the power supply and a user device. The wireless connection can be a Bluetooth connection. The user device can be a smart phone, tablet, laptop, or the like. The method also includes determining a change in the wireless connection. The change can be termination of the wireless connection, for example, when the user device moves a given distance away from the power supply. The method further includes providing a notification to the user device that the change in the wireless connection has occurred. The notification can be visual, audio, combinations thereof, or the like.

The method is applicable when the power supply is plugged into an external power source. The method can also be applicable when the power supply is utilizing an internal battery as a power source.

Embodiments of the present invention provide functionality that extends the capabilities to power provisioning and control. As an example, embodiments of the present invention provide for setting priorities for charging of devices along with an internal battery of the power supply. Additional description related to functionality and control/interaction through a mobile application are provided herein.

Wireless communication between the power unit and an electronic device, for example, a smart phone, enables authentication prior to making a physical connection that is not available in conventional devices. Setting of the charging priorities, as discussed in relation to FIG. 11, can be accomplished wirelessly using the wireless communications capabilities provided by some embodiments. Although some embodiments are described in terms of Wi-Fi communications, the present invention is not limited to this particular communications protocol and other communications protocols are included within the scope of the present invention, including Bluetooth and other communications protocols. Thus, by providing a WiFi hotspot, embodiments enable control of the power unit using wireless communications in addition to wired communications.

The inclusion of a WiFi hotspot 720 in some embodiments enables the power unit to serve as a WiFi access point, eliminating the need to utilize a WiFi hotspot separate from the power supply that is used, for example, to operate a laptop computer. The WiFi hotspot can be utilized as a range extender since it has access to external power, extending the range in comparison to a battery operated device.

According to embodiments of the present invention, a mobile application (also referred to as an app) is provided that can interact with a power adapter including accessories as described herein. In a particular embodiment, power provisioning and control of the power adapter are provided through the mobile application. Without limiting embodiments of the present invention, the mobile application described herein provides for setup, management, and performance monitoring of a power adapter having multiple outputs (e.g., three output ports), also referred to as a multiple port power adapter along with one or more accessories. The power adapter is useful for powering and charging of multiple electronic devices concurrently. The present invention is applicable to a broad range of power adapters, including single output power adapters as well as multiple output power adapters.

Embodiments of the present invention relate to a mobile application that enables users to perform configuration of the multiple output port power adapter with accessories and monitoring of the charging processes. As described herein, the configuration process includes defining prioritization of the charging of devices connected to the power adapter. Merely by way of example, since the multiple output power adapter has a maximum power output value, it is possible that the sum of the loads associated with the devices connected to the power adapter could exceed the maximum power output value (also referred to as a power rating). To address this issue, prioritization of the charging processes enables charging of multiple devices such that the power rating is not exceeded. In addition, power delivery to accessories can be managed using embodiments of the present invention.

According to an embodiment of the present invention, a method of prioritizing powering processes is provided. The method includes establishing a communications channel between a control device and a power adapter having a power rating, a plurality of output ports, and one or more accessories. A first output port of the plurality of output ports has a first maximum power level and is operable to power a first electronic device and a second output port of the plurality of output ports has a second maximum power level and is operable to power a second electronic device. The method also includes presenting, to a user, a list of electronic devices including the first electronic device and the second electronic device and defining a prioritization for powering of the first electronic device and the second electronic device. The prioritization ranks the first electronic device higher than the second electronic device. The method further includes providing a first output power at the first output port operable to power the first electronic device, determining that concurrent powering of the second electronic device will exceed the power rating of the power adapter, and providing a second output power at the second output port less than the second maximum power level.

According to another embodiment of the present invention, a method of monitoring one or more charging processes is provided. The method includes establishing a communications channel between a control device and a power adapter having a first output port and one or more accessories and defining a relationship between a first electronic device and the first output port. The method also includes displaying, in a graphical user interface, a status of the first electronic device.

According to a specific embodiment of the present invention, a method of displaying charging priorities for a plurality of electronic devices is provided. The method includes establishing a communications channel between a control device and a power adapter having multiple output ports and one or more accessories and associating a first priority with a first electronic device having a first charging profile. The method also includes associating a second priority with a second electronic device having a second charging profile and displaying, in a graphical user interface, a charging priorities table including the first priority, a reference to the first electronic device, the second priority, and a reference to the second electronic device.

According to another specific embodiment of the present invention, a method of displaying charging thresholds for a plurality of electronic devices is provided. The method includes establishing a communications channel between a control device and a power adapter having multiple output ports and one or more accessories and defining a first charging threshold for a first electronic device having a first charging priority. The method also includes defining a second charging threshold for a second electronic device having a second charging priority. The method further includes displaying, in a graphical user interface, a charging priorities table including the first charging priority, a reference to the first electronic device, and the first charging threshold and the second charging priority, a reference to the second electronic device, and the second charging threshold. Additionally, the method includes charging the first electronic device at a first charging rate.

According to a particular embodiment of the present invention, a method of operating a power adapter having multiple outputs and one or more accessories is provided. The method includes setting an output priority for each of the multiple outputs and providing an output voltage at each of the multiple outputs. The method also includes measuring one or more operating parameters of the power adapter and determining that at least one of the one or more operating parameters are greater than a setpoint. The method further includes reducing the output voltage associated with at least one of the multiple output ports.

Embodiments of the present invention can be utilized with a variety of mobile devices, including mobile devices compatible with both iOS as well as Android, although other operating systems, including Blackberry, Windows Phone 8, Symbian, and the like are included within the scope of the present invention. Thus, mobile devices suitable for use with the present invention include mobile phones, tablets, e-readers, game consoles, portable (e.g., laptop) computers, and the like. Moreover, embodiments of the present invention provide for integration with social media sites 134, including Facebook, Twitter, and the like.

In addition to interaction with power adapter, the mobile application is able to receive push notifications from external sources, such as a website related to the power adapter. These push notifications can include information on new products, accessories, product promotions, and the like. Additionally, software updates can be delivered to the mobile application for further delivery to the power adapter. One of ordinary skill in the art would recognize many variations, modifications, and alternatives.

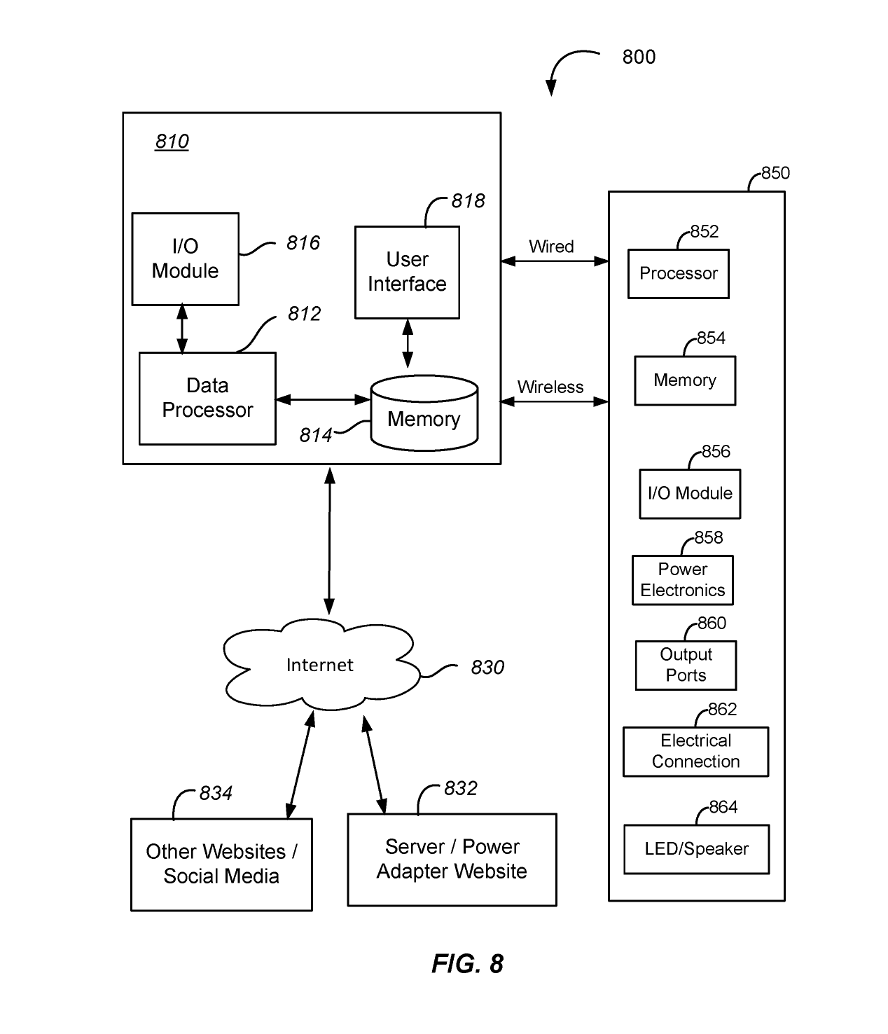

As illustrated in FIG. 8, the mobile device 810 includes an input/output module 816 that is operable to communicate with server 832 through the internet 830. Interacting with server 832, the mobile application enables the user to interact with various external programs such as a tip configurator used to specify the proper tip to be used with a particular laptop computer, perform device selection, and provide access to user manuals that are available through on-line sources. As illustrated in FIG. 8, the input/output module 816 can detect the presence of an internet connection and display the presence or absence of the internet connection through the display 816. As an example, if no Internet connection is detected by the I/O module, an appropriate user notification can be displayed through the display, through an audio output, or the like.

The display 816 is able to support a series of graphical user interfaces (GUIs) that are utilized to receive and communicate information related to the power adapter.

Memory 814 is operable to store data related to the power adapter, including default configuration settings, the latest user-defined configuration settings, historical configuration settings, power consumption information, or the like. Other functionality provided by the mobile device, for example, calendar and clock functionality, can be utilized by and in conjunction with the mobile application interacting with the power adapter. For example, the integration with Calendar and Clock functionality on the mobile device enables the mobile application to perform scheduling functions and synchronization of LED operations with the clock or alarm.

The power adapter 850 includes a processor 852 and a memory 854. The processor is used to process data related to the devices connected to the power adapter as well as data related to power adapter performance as described more fully herein. An I/O module 856 is provided to interact with the I/O module 816 in the control device 810. Using the I/O module 856, the power adapter 850 can interact with the control device 810 through either wired (e.g., USB) or wireless (e.g., Bluetooth) connections. Power electronics 858 provide power to one or more output ports 860. In some embodiments, the power adapter 850 includes a plurality of output ports, with some output ports operable to provide a higher output power level than other of the output ports. In a particular embodiment, a laptop computer can be connected to one of the output ports that provides a suitable output power appropriate to power or charge a laptop computer.

The power adapter 850 also includes an electrical connection 862, for example, electrical prongs, that enable the power adapter to be plugged into a supply of electrical power. In some embodiments, the power adapter can include a battery to supplement the power provided through the electrical connection 862. Indicators in the form of an LED and/or a speaker can be provided to provide for feedback from the power adapter and monitoring of the power adapter.

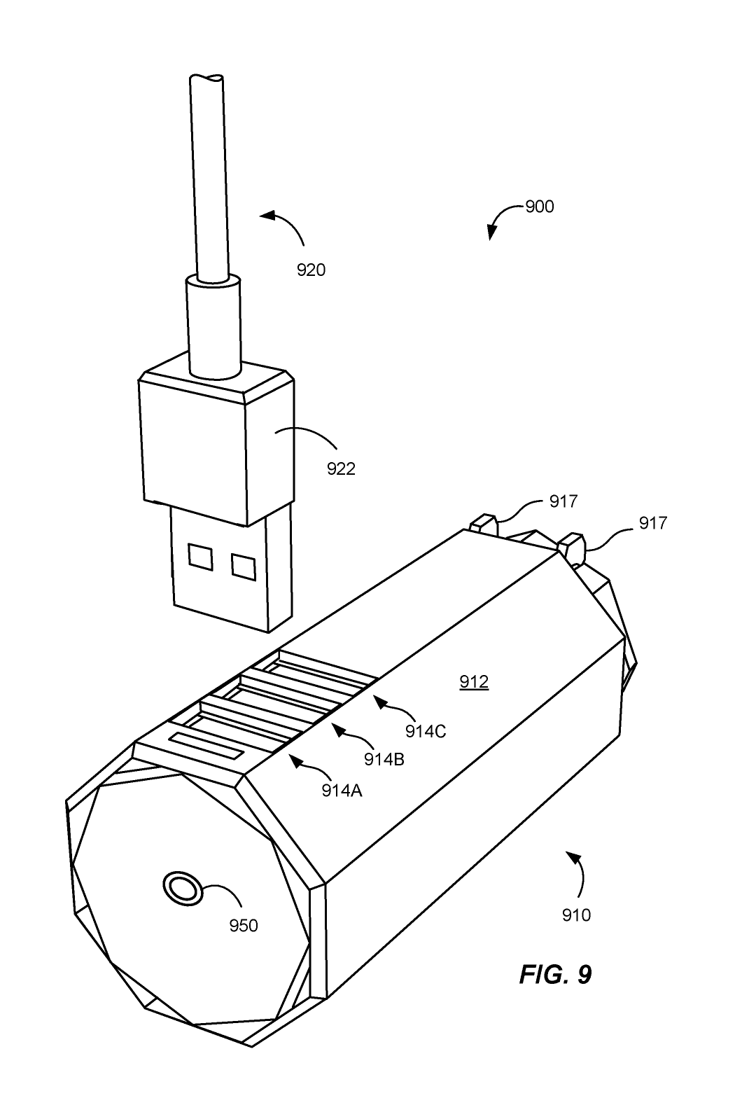

FIG. 9 is perspective diagram of a variable output power adapter and a communications cable suitable for use with embodiments of the present invention. It should be noted that the communications cable is operable to carry both communications and power. As illustrated in FIG. 9, the variable output power adapter 910 can be connected to communications cable 920, which in turn, is connected to a mobile device (not shown). The power adapter 910 includes a housing 912 and a plurality of output ports 914A, 914B, and 914C, also referred to as output connections. In the illustrated embodiment, there are three output ports, but this is not required by embodiments of the present invention and other number of output ports, including two, four, five, six, or more, can be provided. Embodiments of the present invention are applicable to a variety of power adapters and the mobile application supports the three output port power adapter illustrated in FIG. 9 as well as other power adapters as described herein.

The plurality of output ports 914A, 914B, and 914C differ, with one or more of the output ports providing a variable voltage output depending on the type of cable connected to the output connection. In some embodiments, one of the plurality of output ports, for example, output port 914A is operable to output multiple voltages depending on the configuration or type of the cable and is thus referred to as a variable voltage output port. As an example, the output port 914A can operate as a standard 5 V compliant USB port when a standard USB cable is connected. However, when a special cable is connected, the operation of the output port 914A is modified to operate at a higher voltage (e.g., 19.5 V), which is suitable for charging a laptop computer. Thus, the output port 914A is variable depending on the cable that is connected, providing functionality not available using conventional designs.

It should be noted that in the embodiment illustrated in FIG. 9, a USB cable with USB connector 922 is utilized as the communications cable 920 that provides both communications and power. However, this is not required by the present invention and other connector designs can be utilized including standardized and proprietary connector designs, including plugs, receptacles, and terminal blocks. One of ordinary skill in the art would recognize many variations, modifications, and alternatives.

Referring to FIG. 9, the communications cable 920 has a USB connector 922 that can be inserted into the ports of the power adapter. As described more fully herein, connection of the communications between the power adapter and the mobile device enables communication between the mobile device and the power adapter, for example, in the context of the mobile application described herein.

In addition to communication between the mobile device 810 and the power adapter 850 through a wired connection as illustrated in FIG. 9 (e.g., a USB connection), wireless connections can be established to complement or supplement a wired connection. Examples of wireless connections include Bluetooth connections and the like.

The power adapter 910 also includes an LED 950 or other light emitting device that is positioned on housing 912. The LED is utilized to provide information on the status of the power adapter as well as other functions as described herein. The LED can be a single color LED or a variable color LED depending on the application. Although the LED 950 is illustrated on an end of the housing 912, this is not required the position of the LED, the number of LEDs, and the like can be modified to meet the particular system objectives.

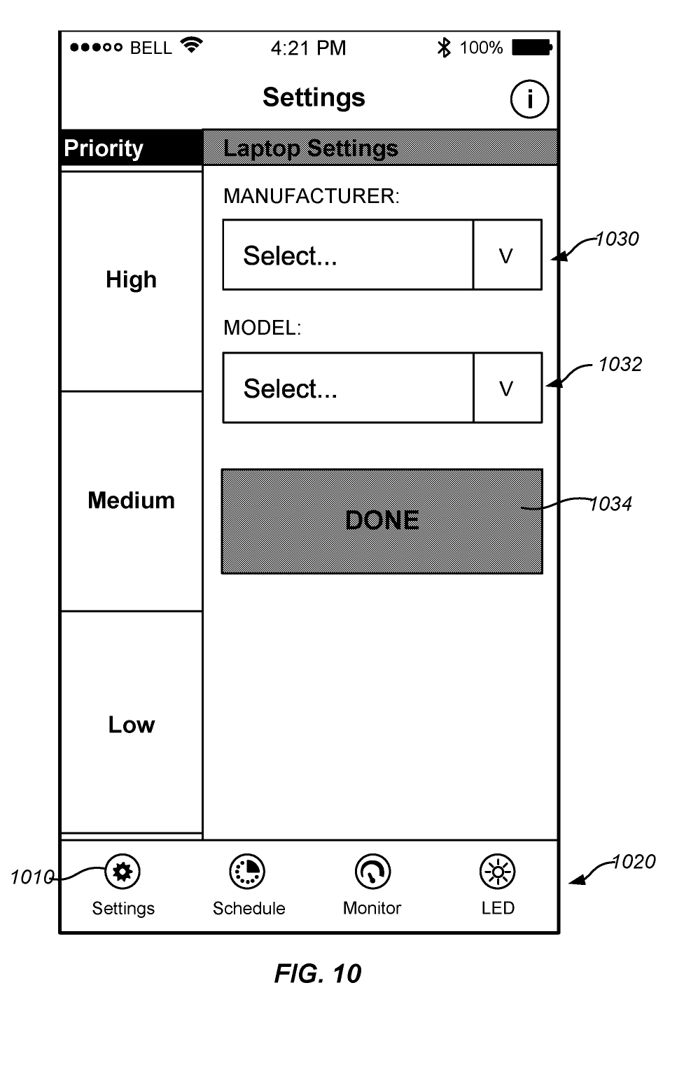

FIG. 10 is a simplified graphical user interface illustrating system settings according to an embodiment of the present invention. Referring to FIG. 10, system settings are accessible through selection of the Settings icon 1010 in the icon tray 1020 disposed at the lower portion of the graphical user interface in this embodiment. The Settings icon 1010 is modified to become brighter, change color, or the like when the Settings icon is selected. One of ordinary skill in the art would recognize many variations, modifications, and alternatives. The graphical user interface illustrated in FIG. 10 enables a user to select a manufacturer and model number of devices that will be associated with differing charging priorities as described more fully herein.

According to embodiments of the present invention, the mobile application provides a variety of functions related to the power adapter. Initially, a communications connection is established between the mobile application and the power adapter. As illustrated in FIGS. 8 and 9 and discussed above, the communications connection can be through a wired connection, for example, a USB cable, or through a wireless connection, such as Bluetooth. After establishing a connection between the mobile device and the power adapter, a configuration process can be performed to customize the power adapter to the particular electronic devices that that user desires to use with the power adapter.

After communication is established, the mobile application will read the firmware and hardware model versions of the power adapter from registers in the power adapter. This information enables the mobile application to tailor the functionality and subsequent screens to the specific power adapter model that is being utilized. In addition, the mobile application will read power adapter settings from registers containing configuration settings and compare them to the configuration settings stored in the memory of the mobile device. In an implementation, the configuration settings stored in the memory are the settings that were used by the mobile application during its last time being operated. In case the configuration settings in the power adapter and settings stored by in the mobile application are different, the mobile application can display a message advising the user that the settings are different and providing the user with an opportunity to select the settings that are desired. In another embodiment, the user can confirm that it is acceptable to apply the settings that are stored by the mobile application. One of ordinary skill in the art would recognize many variations, modifications, and alternatives.

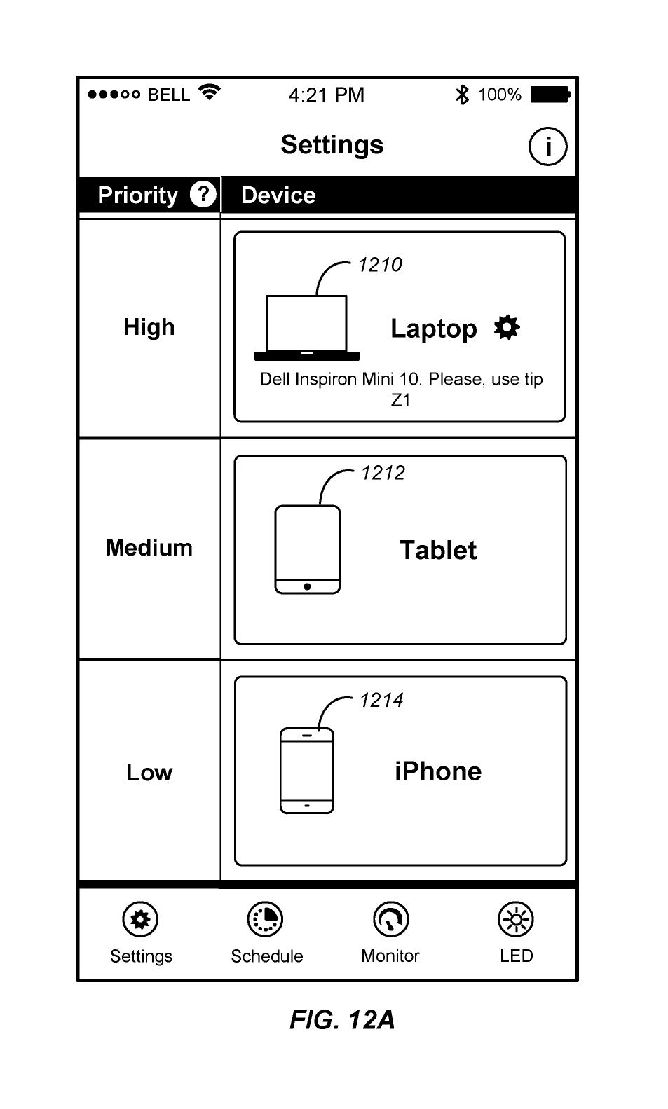

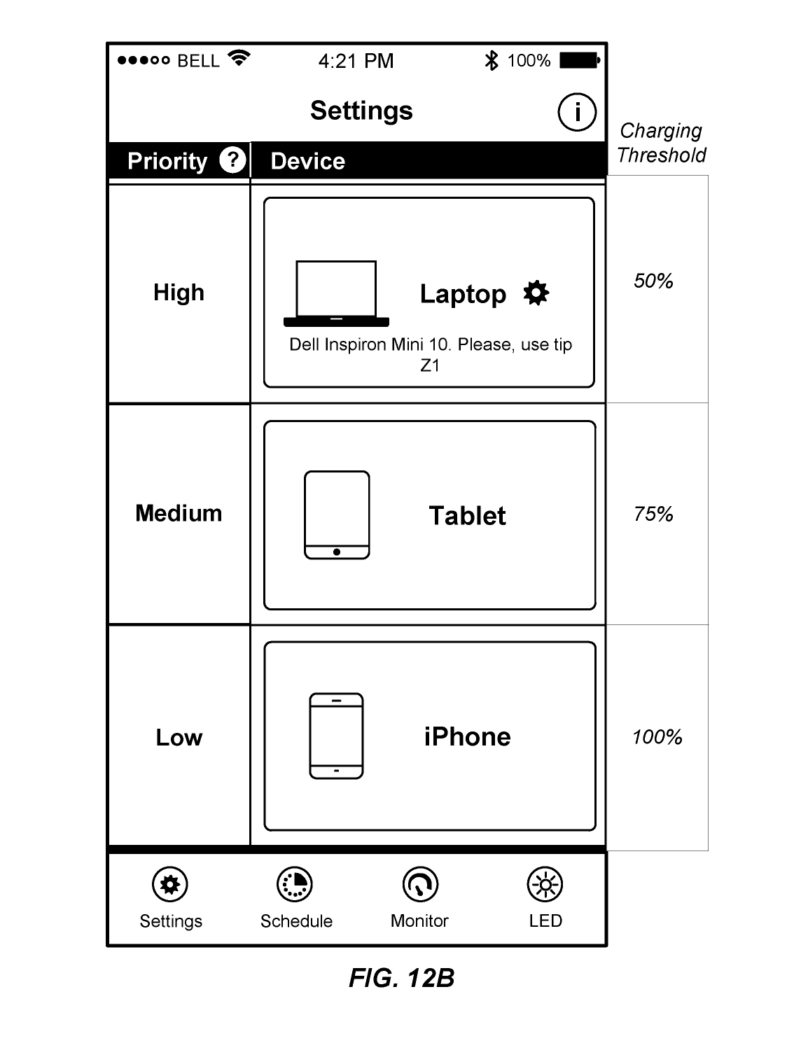

Referring once again to FIG. 10, the Settings graphical user interface enables the user to select a laptop manufacturer's name and the laptop model from a configuration menu associated with the output port for the laptop. Manufacturer selection area 1030 and model selection area 1032 are illustrated in FIG. 10 and allow the user to select the laptop settings, i.e., manufacturer and model. A list of manufacturers and particular models for the selected manufacturer can be provided through a drop down list or through other suitable means. After selecting a manufacturer and a model, the user selects the DONE button 1034 to proceed to the next phase of the setup process. In response to the user selections, the mobile application is able to display the part number of other identifier for the laptop tip as illustrated in FIG. 12A and record the laptop configuration information in memory. In addition to manufacturer and model number, other information related to the laptop, including model-specific information such as the model identification code (CONFIGLAP), maximum output voltage (VOUTMAX), maximum output current (IOUTOCP), pulse width modulation duty cycle data (PWMDUTY), an EEPROM ID for the laptop (EPROMID), tip identifier (Tip), and the like can be recorded in memory. As will be evident to one of skill in the art, some laptop charging cables include, not only positive and ground for electrical charging, but a third or other additional wire that can be used to communicate configuration or identification information. Some embodiments of the present invention can utilize charging cables that include the third wire to read or provide configuration information, such as the EEPROM ID to ensure compatibility.

Table 1 is an exemplary lookup table containing laptop configuration information. The data in Table 1 is provided to illustrate configuration information for a default laptop and an HP laptop. This table is not intended to limit the information that can be obtained and stored, but is merely provided by way of example.

TABLE 1

| Mfg | Model | CONFIGLAP | VOUTMAX | IOUTOCP | PWMDUTY | EPROMID | Tip |
|---|---|---|---|---|---|---|---|
| Default | Default | 00 | 19.5 | 4.0 | 50 | 00 | |
| HP | Envy 4 | 10 | 19.5 | 3 | 50 | 10 | Z7 |

In an embodiment, during the process of selecting the manufacturer and model of a device, the power or charging cable utilizes an additional wire (e.g., the third wire) to communicate the proper identification code to the device, which thereby identifies the power adapter as an OEM power adapter for the particular device. In an embodiment, this process can be automated such that when the graphical user interface illustrated in FIG. 10 is used to set the manufacturer and model, the configuration information is then provided to the device to enable operation in native mode.

In the absence of a user's input for the laptop configuration, a default set of configuration settings can be used. This configuration is illustrated in Table 1 as the Default model. If, during the configuration process, the user is not able to find a specific laptop model in the lists provided through the manufacturer selection area 1030 and model selection area 1032, the a message can be displayed to the user in the Settings graphical user interface to advise the user to update the mobile application. Updating of the mobile application to the latest version will provide the user with additional options for the laptop listings. If the mobile application is running the current version, then a message can be displayed to the user in order to inform the user that a default or predetermined set of values are being utilized.

It should be noted that if communication cannot be established between the mobile device and the power adapter, then a message prompting the user to check cable connections can be displayed.

FIG. 11 is a simplified graphical user interface illustrating system priority settings according to an embodiment of the present invention. In this Settings graphical user interface, charging priority is listed in a left hand column and devices that can be operated or charged using the power adapter are listed in a right hand column. The right hand column includes a plurality of tiles 1110, 1112, and 1114 that include icons associated with particular devices.

As illustrated in FIG. 11, since the power adapter has multiple output ports, the mobile application is useful in setting the charging priority for the various output ports. In an embodiment, default priorities are defined by settings that are stored in a register in the power adapter, a register in the memory of the mobile device, or the like. By default, in some implementations, the charging priority is set to laptop, then tablet, then phone (e.g., a smartphone) as illustrated in FIG. 11, in which the laptop has a high priority, the tablet has a medium priority, and the phone has a low priority. These priorities are shown to the user by moving or dragging the tile for each device to a position adjacent the desired charging priority. In the illustrated embodiment, the priorities are fixed and the tiles are movable, but the present invention is not limited to this implementation and in other embodiments, the priorities are movable or both the priorities and tiles are movable. One of ordinary skill in the art would recognize many variations, modifications, and alternatives.

Embodiments of the present invention enable a user to modify the charging priority. In FIG. 11, the vertical arrow displayed between the tiles including the laptop and tablet device icons illustrates the ability of the user to modify the default priorities and to set different priorities between the output ports of the power adapter (e.g., the Laptop, Tablet, and Phone output ports). When a user selects priorities High (e.g., Priority 1) and Medium (e.g., Priority 2), the remaining output can be automatically set to priority Low (e.g., Priority 3).

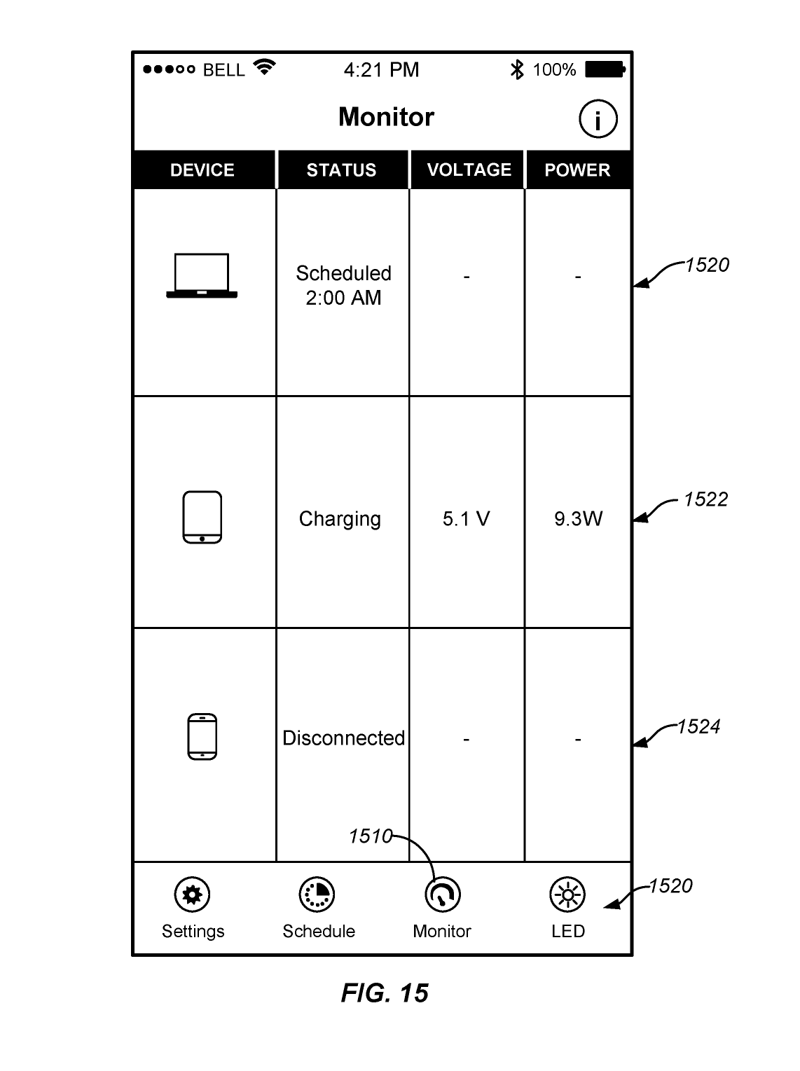

It should be noted that an association can be made between devices and output ports by the power adapter. Although output port 914A is typically associated with a laptop computer and output ports 914B and 914C are associated with a tablet and a smartphone, respectively, this is not required by the present invention. In some embodiments, information related to a particular device is stored by the memory of the power adapter and when that particular device is plugged into a given output port, the power adapter recognizes the particular device and then uses the device information in the various graphical user interfaces described herein. Referring to FIG. 15 below, the device column includes an icon for each of the three devices. Using the association between the output ports and the devices, the Monitor screen is able to show the status of the various devices, for example, that the smartphone is disconnected, independent of the actual output port to which the smartphone is connected.

It should be noted that in some implementations, the order in which device characteristics are defined (FIG. 10) and power/charging priorities are set (FIG. 11) are varied, with device characteristics being defined before or after setting of charging priorities. In other implementations, the default settings can be utilized, enabling the user to start using the power adapter and then modify the performance characteristics of the power adapter after the initial use.

FIG. 12A is a simplified graphical user interface after setting charging priority according to an embodiment of the present invention. In FIG. 12A, the priority with which the various devices will be charged is shown for the user, including information on the various devices, which can include manufacturer and model number, information that is specific to the particular electronic device, such as which charging tip to use with a particular laptop, nicknames for the devices, and the like. Utilizing the interface illustrated in FIG. 12A, the user can utilize the mobile application to implement prioritization of devices that enables the user to effectively program the adapter with the identity of the device that is the most important to charge, the second most important to charge, and so on, to the device that is the least important to charge. In some embodiments, the power adapter will attempt to charge all connected devices. If the total amount of power needed to charge all the devices exceeds the power rating of the power adapter, which can be indicated by an increase in operating temperature, current exceeding a current limit at a predetermined voltage, output power exceeding the power adapter's power limit, or the like, the power adapter will start reducing the amount of power available for charging by throttling back the charging process of the lowest priority device. If additional load shedding is appropriate, the device with the next highest priority, and so on, is throttled back until the power adapter is operating at the desired power level. Herein, embodiments are included that can utilize reducing current, reducing voltage, average values of current and/or voltage, or combinations thereof to reduce output power.

Embodiments of the present invention enable a user to plug devices into all of the available output ports, even if the sum of the charging powers for the devices exceeds the power rating of the power adapter. Using the prioritization process described herein, although all devices are plugged in, the power delivered to each of the output ports will be managed by the power adapter to charge the devices without overloading the capabilities of the power adapter. As an example, if a three output power adapter has a power rating of 80 W, a user may plug in a laptop that consumes 65 W using the first output port, a first tablet that consumes 12 W using the second output port, and a second tablet that consumes 12 W using the third output port. Since the sum of the power consumptions is 89 W and exceeds the 80 W power rating of the power adapter, the prioritization process will reduce the power delivered to one or more of the devices to operate at a power output of less than or equal to 80 W.

Thus, embodiments of the present invention provide a user experience in which the user can plug devices into all available output ports and all the devices will be charged, but at different rates depending on their priority. In some embodiments, the priority is set by the user through the mobile application. In other embodiments, the priority for charging is set by default, with the first output port (a high power port suitable for a laptop) as the highest priority, the second output port (suitable for a tablet or phone) as the next highest priority, and so on through the last output port.

In an exemplary use case, the user plugs two or more devices into the power adapter and all devices start charging. If one or more parameters associated with the power adapter begin to exceed predetermined thresholds, which can be referred to as a setpoints, then the power adapter output power is reduced by reducing the output power of one or more of the output ports in one of several manners.

In order to reduce the power provided to one or more of the output ports, an output port can have the output power reduced to zero or the reduced power output ports can be operated in a pulse width modulation (PWM) mode in some embodiments. Operation in the PWM mode enables several charging scenarios when the combined power consumption of the connected devices exceeds the power rating of the power adapter.

A first mode of PWM operation reduces the duty cycle of the power delivered to the lowest priority device. In the above example, the duty cycle of the power delivered to the second tablet is decreased from 100% to 25%, producing an average power of 3 W for the second tablet. Thus, the second tablet would be charged at a rate four times slower than the first tablet. This reduction in the duty cycle of the third output port provides an operating power level of 80 W (65 W+12 W+3 W) for the power adapter. Repetition rates for PWM cycles are in the hertz range (e.g., 0.1-1 Hz) for some implementation. Thus, this first mode of PWM operation provides a mechanism for reducing average power consumption by reducing the duty cycle of the output voltage or current, i.e., reducing the average voltage and/or current.

A second mode of PWM operation maintains the average power of the power adapter at a predetermined power level (e.g., 80 W in this example) by operating for a first time period at a power level that exceeds the power rating of the power adapter (i.e., charging all three devices for the first time period, such as a number of seconds, thereby operating at 89 W in the above example) and then operating for a second time period at a power level that is less than the power rating of the power adapter. In this second mode, following along with the above example, the power adapter would charge the second tablet using the third output port for a first time period (e.g., 3 seconds) and then set the third output port to 0 V for a second time period (e.g., 9 seconds). The average power of the power adapter will be (89 W×¼)+(77 W ¾)=80 W. In a manner similar to the first PWM mode, the second tablet is charged at a rate four times slower than the first tablet.

In the PWM modes, the limits can be values other than zero and 100% of the rated power. Some embodiments utilize limits of zero and 100%. Other embodiments utilize a first limit greater than or equal to zero and a second limit that exceeds the rated power. One of ordinary skill in the art would recognize many variations, modifications, and alternatives.

Another mode of providing reduced output power utilizes device settings that enable the device to be charged at various rates. As an example, some devices can determine the current available from a charging port (e.g., by reading a voltage on a pin of a charging port) and then adjust their charging current accordingly. This variation in charging rate enables the device to be charged at a high rate when the power adapter is operating at less than its rated power and to be charged at a lower rate when the power adapter reduces the output power available at one of the lower priority output ports.

In an embodiment, a port emulator is integrated in the power adapter that under the control of a controller, can emulate output ports having differing charging current capabilities. For example, an output port connected to a tablet is configured to initially provide an output power of 12 W. The tablet senses the 12 W configuration, typically by reading a voltage on a voltage divider integrated with the output port, and initially draws 12 W of power during charging. In order to reduce the power provided at the output port, the port emulator modifies the configuration of the output port (e.g., by modifying the voltage of the voltage divider) to provide an output power of 5 W. When the tablet in this example senses the modified configuration, the device reduces its charge consumption to consume 5 W in accordance with the 5 W output power of the port.

In other implementations, a command is sent to the device (either through the wired connection or wirelessly) to provide modified configuration information for the output port, thereby reducing the charge consumption by the device to effect the desired power reduction for the output port. Thus, embodiments provide the ability to reduce power output for a port based on decreased power output by the port, decreased power consumption by the device, combinations thereof, or the like. One of ordinary skill in the art would recognize many variations, modifications, and alternatives.

In addition to these modes of managing power consumption, other modes are included within the scope of the present invention, including hardware-based solutions, software-based solutions incorporating communication between the device and the power adapter related to the power available on a given port, and the like.

The graphical user interface utilizes a charging priorities table that includes information on the charging priority for the various electronic devices (e.g., High, Medium, and Low) as well as a graphical representation of the various electronic devices (Laptop icon 1210 Tablet icon 1212, and smartphone icon 1214). Nicknames or other identifiers for the various electronic devices (e.g., Laptop, Tablet, iPhone) are displayed adjacent the graphical representations of the various electronic devices. In some embodiments, either a graphical representation or an identifier is utilized rather than the combination illustrated in FIG. 12A. Additionally, the graphical user interface can include information on the various devices, such as manufacturer and model number, as well as other pertinent information (e.g., the tip that is associated with a particular laptop).

In FIG. 12A, the charging priorities table is laid out with the charging priorities in a first column and the devices in a second column, but this is not required by the present invention. Although the charging priority (e.g., High) and the electronic device information, including the reference to the electronic device, are illustrated in a single row, this is merely exemplary and other layouts are included within the scope of the present invention.

In some embodiments, multiple devices may be assigned a single priority. For example, two devices may be assigned high priority and one device can be assigned low priority, with no medium priority assignment. In this case, if the power consumption of the two high priority devices exceed the power rating, both of these high priority devices can be charged at a less than maximum rate using the PWM mode or the like. Extension of this situation to a case in which all devices are high priority would result in all devices charging at less than maximum rates. One of ordinary skill in the art would recognize many variations, modifications, and alternatives.

In contrast with conventional power adapters having multiple outlets (e.g., identical outlets), embodiments of the present invention enable the prioritized charging of multiple electronic devices. The ability to program the power adapter through the mobile application thus enables a user to set and modify the charging priorities depending on the user's particular needs. In some implementations, the overall power output of the power adapter is monitored, for example, through an operating temperature or an operating current. Initially, the power adapter will attempt to charge all connected devices while monitoring the overall power output. As the power output reaches the power rating, the prioritization will be used to reduce the average output power of one or more of the output ports to achieve an overall power output within the power rating.

FIG. 12B is a simplified graphical user interface illustrating charging priority and charging thresholds according to an embodiment of the present invention. In addition to prioritizing device charging as described above, the mobile application provides a mechanism for the power adapter to provide enhanced charging profiles that include charging thresholds for the various devices. As illustrated in FIG. 12B, a charging threshold column has been added to the graphical user interface, enabling the user to set the charging threshold for one or more of the devices. In comparison with FIG. 12A, where the charging thresholds are effectively set at 100% for each of the devices, the charging thresholds can be set using the graphical user interface illustrated in FIG. 12A such that once the charging threshold is reached, devices with lower priority can be charged and then higher priority devices can be charged to a higher charging threshold at a later time.

In FIG. 12B, the charging threshold for the laptop has been set to 50%, the tablet to 75%, and the phone to 100%. By defining both priority and charging thresholds, the user is able to control charging processes in a manner not available using conventional techniques. As an example, if the user has a limited time to charge all of their devices, the user can specify that they want the laptop be 50% charged, the tablet to be 75% charged, and the phone to be fully charged. In terms of priority, the user wants to ensure that the laptop is 50% charged, for example, before the user moves to a location without charging capabilities. As described herein, embodiments provide a dynamic charging priority that varies charging priority based on charging thresholds.

In an exemplary use case, initially, all three devices will be charged by the power adapter. When the power adapter reduces output power, the phone will either stop being charged, or charged at a lower rate than the other devices. Once the laptop, which is receiving highest priority charging, reaches the 50% charging threshold, the charging priorities will be modified such that the laptop stops charging and the phone initiates or resumes full charging until the phone is 100% charged. Once the phone is fully charged, charging of the laptop toward a full charge can resume. Thus, in this embodiment, the priority can be dynamically overridden by the charging thresholds once the charging thresholds for higher priority devices are achieved. In a similar manner, if the charging rate of the tablet had been stopped or lowered, once the laptop reached the desired charging threshold, the tablet would be charged to 75%. Once all devices have reached the desired charging threshold, charging priority reverts to the priorities defined by the settings.

In some embodiments, device scheduling can be integrated with the illustrated priority and charging thresholds, providing the user with feedback that not all goals can be accomplished in a given time. Such feedback can then be used by the user to reprioritize the devices, modify the charging thresholds, modify the scheduled charging times, combinations thereof, or the like.

Because electricity rates vary as a function of time during the day/night, along with other reasons, the mobile application provides a user with the ability to schedule charging for specific times. Using a conventional power adapter, charging begins when a device is plugged into the adapter. However, a user who plugs in a laptop during peak hours (e.g., 6 p.m.) may want to delay the beginning of the charging process until electric rates have dropped (e.g., until after midnight and before 6 a.m.). Thus, embodiments provide the user with the ability to schedule the charging processes for the various devices connected to the power adapter. In some embodiments, the charging processes can be synchronized with times at which electric rates change. The timing can be provided by an external device, such as a device plugged into the power adapter (e.g., the power adapter can obtain the current time from a phone during the scheduling process) or by an internal clock in the power adapter.

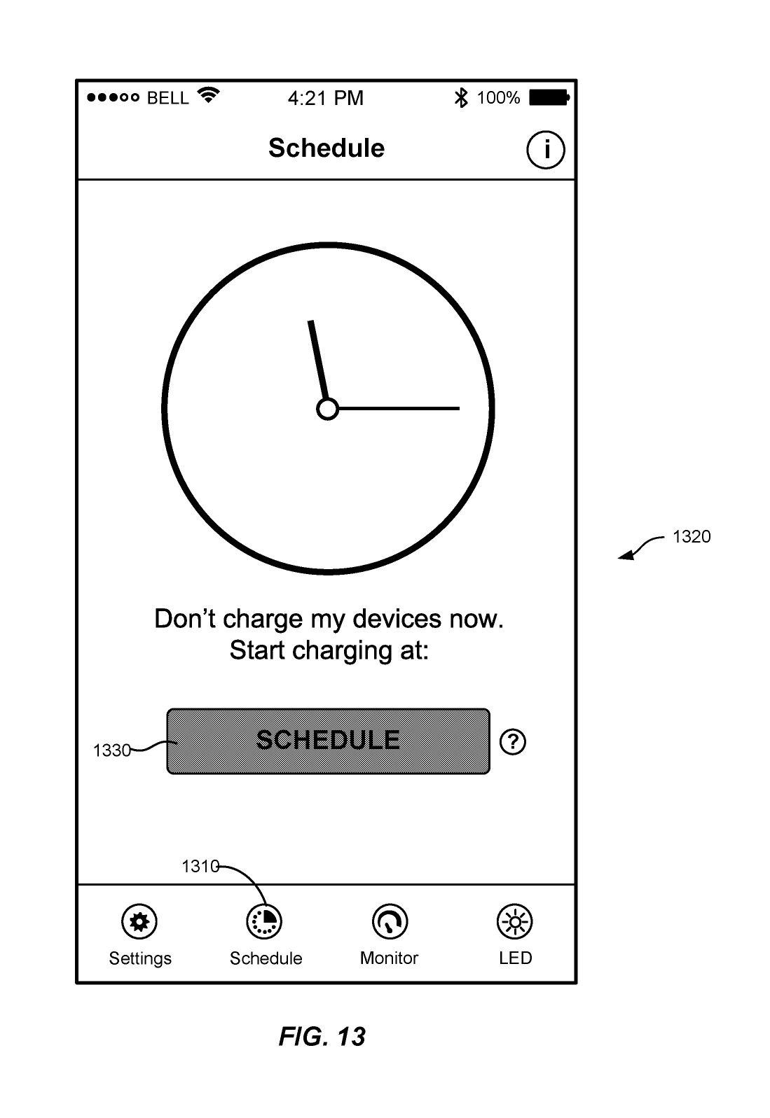

FIG. 13 is a simplified graphical user interface illustrating scheduling of charging according to an embodiment of the present invention. As illustrated in FIG. 13, a Schedule icon 1310 is selected to access the scheduling functions provided by the mobile application. The scheduling functions enable a user to select between starting charging immediately when the electronic devices are plugged into the power adapter, or to schedule charging for a specific time in the future. The period during which charging can be scheduled can be selected by default (e.g., during the next 12 hours) or can be set by the user.

In some embodiments, the estimated charging time for a device can be utilized as part of the scheduling process. For example, if a laptop is plugged in and the user attempts to schedule the laptop for a 4 a.m. start time, the laptop can provide an estimated charging time (e.g., 3 hours) to the power adapter. This information could be used to provide the user with a notification that the charging will not be complete until 7 a.m., which may result in the user shifting the scheduled start time back to an earlier start time (e.g., 2 a.m.) in order to have the charging completed by a desired time at which all devices should be charged (e.g., 6 a.m.), which can be a default time or a time defined by the user. Thus, feedback from the device connected to the power adapter could be utilized during the scheduling process. As an example, the user could define a time at which the device is to be charged. Using feedback from the device, the power adapter can then compute the appropriate start time. One of ordinary skill in the art would recognize many variations, modifications, and alternatives.

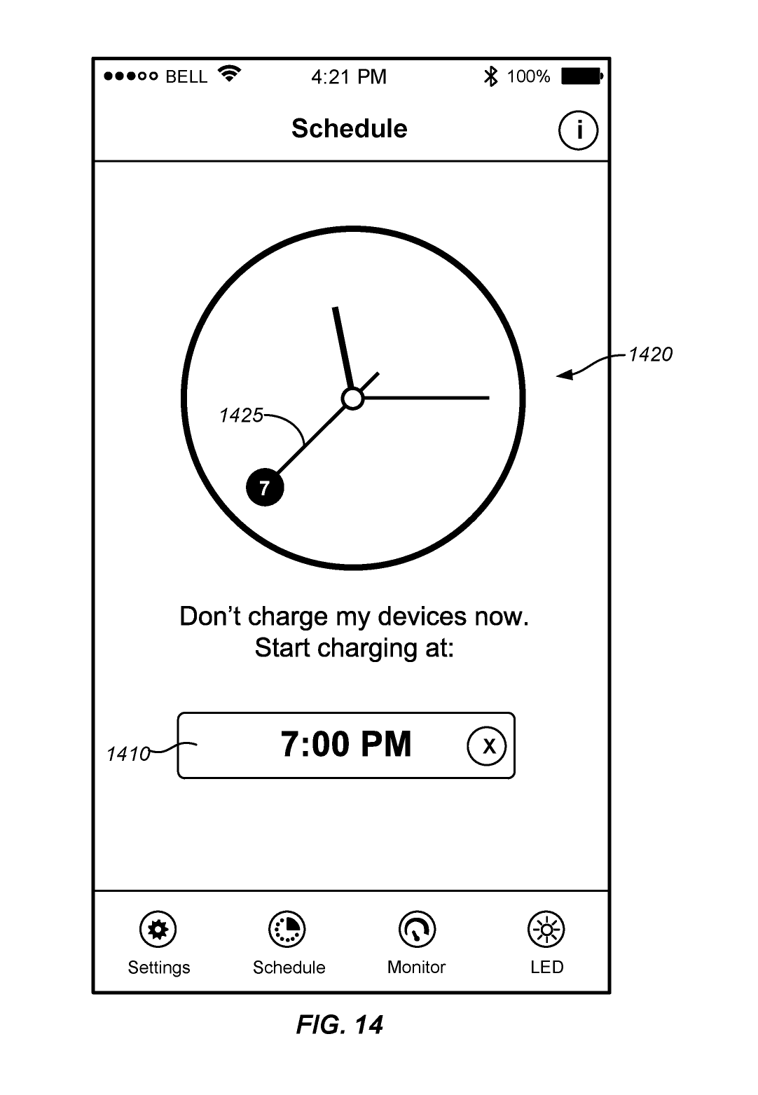

FIG. 14 is a simplified graphical user interface illustrating scheduling charge start time according to an embodiment of the present invention. The user initiates the process of scheduling the charging time by selecting the schedule button 1330 illustrated in FIG. 13. The selection of the schedule button will cause the button to display a time window 1410, which can display a default time (e.g., 7:00 PM in the illustrated example). The time window can provide a drop down menu that enables the user to set the start time for the charging operation. In some embodiments, a clock 1420 is displayed to show the current time as well as a hand 425 indicating the time at which charging will begin.

The scheduling capability provides the user with the ability to time-prioritize the charging processes. Thus, in addition to prioritization of charging power, the user can determine which devices should be charged first and which devices can be charged later, providing a flexibility and control that is not available using conventional systems.

FIG. 15 is a simplified graphical user interface illustrating monitoring of device charging according to an embodiment of the present invention. The monitoring functions of the mobile application are accessed through selection of the Monitor icon 1510 in the icon tray 1520. In the Monitor graphical user interface, the mobile application displays current (e.g., instantaneous) values associated with the status and electrical characteristics of the electronic devices that can be connected to the output ports of the power adapter. Referring to FIG. 15, voltage and power consumption for each of the three outputs of the power adapter are shown in association with the device associated with the particular output. The data in the Monitor graphical user interface is updated on a regular or aperiodic basis, for example, every second, or the like. In addition to the illustrated electrical characteristics, other performance parameters can be monitored, including power adapter temperature (e.g., internal temperature, temperature of one or more components), output current, status of different protections, mode of operation (e.g., PWM), or the like.

As illustrated in FIG. 15, the laptop in row 1520 is scheduled for charging at 2:00 AM. Accordingly, the voltage and power consumption for the output port associated with the laptop is zero. The tablet in row 1522 is currently charging, with 5.1 V being provided at the output port, resulting in a power output at the output port and a corresponding consumption by the tablet of 9.3 W. The phone in row 1524 is currently disconnected and not drawing any power from the power adapter.

In addition to the device information illustrated in FIG. 15, the mobile application can provide the user with information on the status of the power adapter, including a display of the current (e.g., instantaneous) value of the internal power adapter temperature. This temperate data can be updated periodically or aperiodically, for example, every second, every minute, or the like. The display can be in the form of a temperature, a bar graph indicating the temperature, or the like. In case over-temperature protection is triggered for the power adapter, the mobile application will display a notification to the user related to the over-temperature protection, for example, that the adapter has temporarily shut down to prevent overheating and will restart momentarily, that one or more of the output ports has been turned off, that the power being output at one or more of the output ports will be throttled back and the charging time will be increasing, or the like. The information on the temperature of the power adapter enables the user to reprioritize their charging schedule, balance the charging percentages, or the like.

It should be noted that although the monitoring function discussed in relation to FIG. 15 illustrates multiple devices operating in conjunction with a multiple output port power adapter, some embodiments of the present invention are applicable in the context of a single output power adapter as discussed in U.S. Patent Application Publication No. 2015/0357919, herein incorporated by reference. As an example, scheduling and monitoring functionality can be implemented for a single device powered or charged using a single output power adapter.

As an example, embodiments can include a method of monitoring of charging process. The method includes establishing a communications channel between a control device and a power adapter having an output port. The method also includes defining a relationship between an electronic device and the output port and displaying, in a graphical user interface, a status of the electronic device. The status can include a power output level of the output port or a power consumption level of the electronic device.

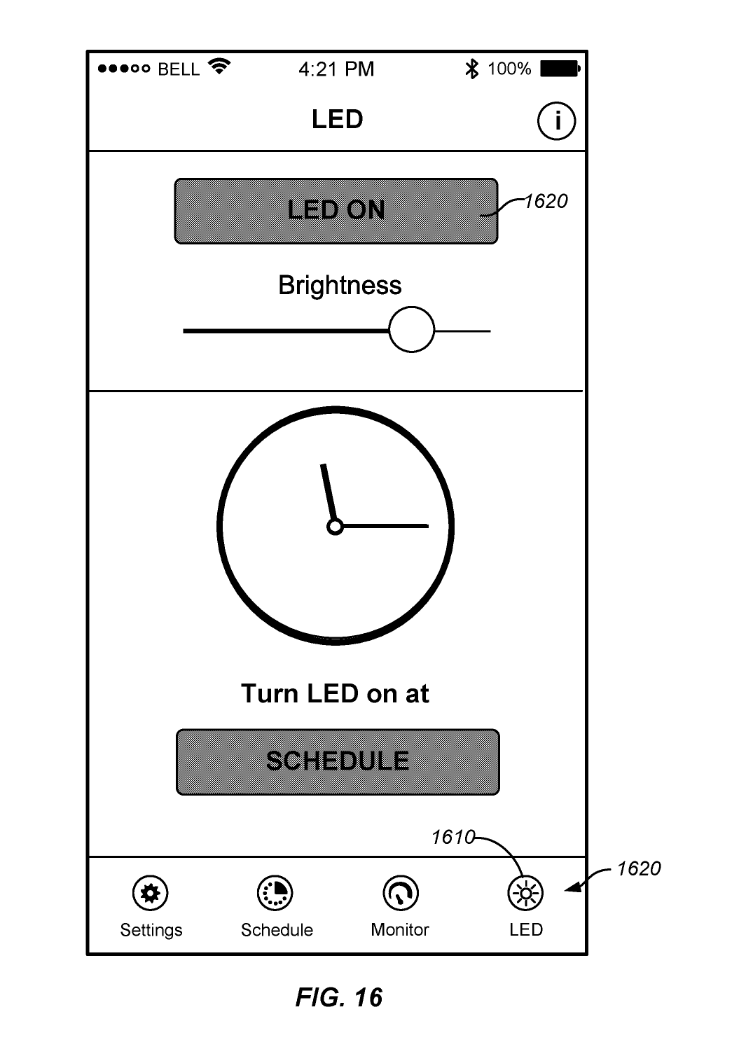

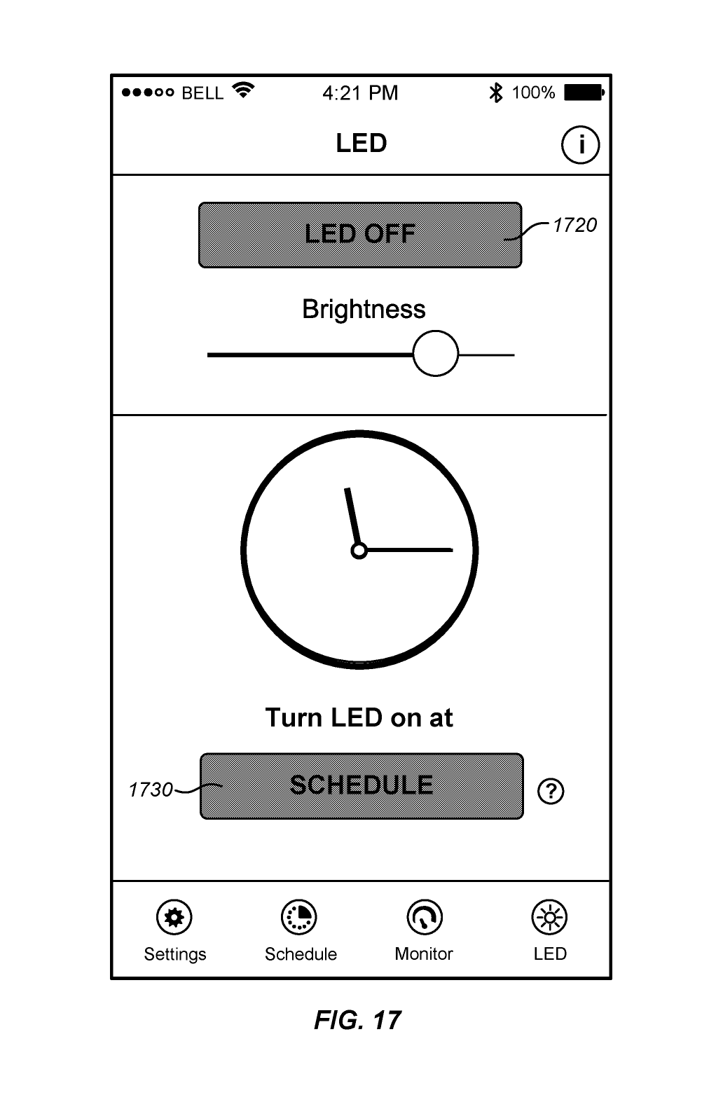

FIG. 16 is a simplified graphical user interface illustrating LED operation according to an embodiment of the present invention. The LED functions of the mobile application are accessed through selection of the LED icon 1610 in the icon tray 1620. The LED graphical user interface as illustrated in FIG. 16 enables a user to modify the brightness of the LED 950. In the LED graphical user interface, the current status of the LED as on (LED ON indicator 1620 in FIG. 16) or off (LED OFF indicator 1720 in FIG. 17) is indicated. Thus, the mobile application displays the status of the LED (ON or OFF).

FIG. 17 is a simplified graphical user interface illustrating scheduling of LED operation according to an embodiment of the present invention. Using the LED graphical user interface, the user is provided with the ability to turn the LED ON/OFF with integrated controls or to schedule the LED turn ON/OFF at specific times, for example, during a predetermined period such as the next 12 hours. Referring to FIG. 17, the user initiates the process of scheduling the LED ON/OFF time by selecting the schedule button 1730 illustrated in FIG. 17. The mobile application enables a user to turn the LED on, either at a predetermined time, or to synchronize the LED with the phone's alarm, so that when the alarm goes off, the LED turns on, or the like.

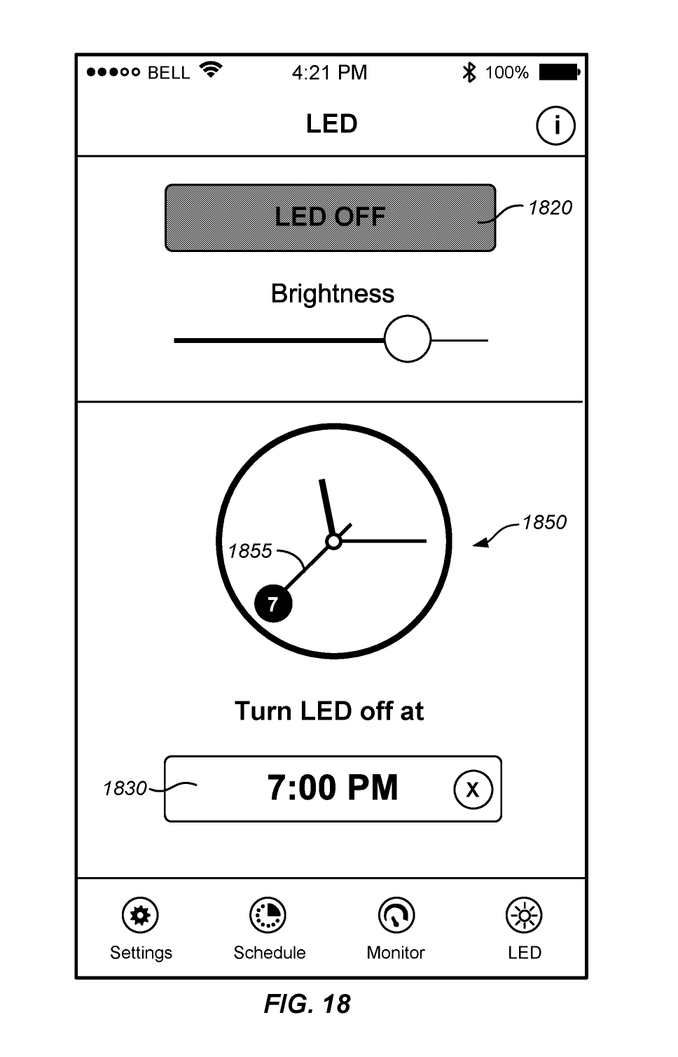

FIG. 18 is a simplified graphical user interface illustrating scheduling of LED extinguishing according to an embodiment of the present invention. The selection of the LED off button 1720 will cause a time window 1830 to be displayed. The time window 1830 can display a default time (e.g., 7:00 PM in the illustrated example). The time window can provide a drop down menu that enables the user to set the time at which the LED will be turned on and/or turned off. In some embodiments, a clock 1850 is displayed to show the current time as well as a hand 1855 indicating the time (e.g., 7:00 PM) at which the LED will turn off.

In addition to control of the LED light through the mobile application, embodiments of the present invention enable a user to synchronize the LED turn on time with a smartphone's alarm.

In addition to the user-side graphical user interfaces illustrated herein, the mobile application has an engineering monitoring (EM) mode. In the EM mode, a service technician is able to send commands and read values of the various registers of the power adapter. The EM mode is useful for engineering and manufacturing personnel and service providers to perform troubleshooting and monitoring of the power adapter. The EM mode is typically inaccessible by default, with login or other unlocking features utilized to enable the service technician to access the EM mode.

Moreover, user support functions are provided by the mobile application. For example, the mobile application can provide access to a User Manual for the specific power adapter model that was identified by the mobile application. The User Manual can be stored on a remote server or inside the mobile application depending on the implementation. Moreover, the mobile application can provide a portal to facilitate purchases of additional power adapters, accessories that are compatible with the specific power adapter model that was identified by the mobile application, and the like.

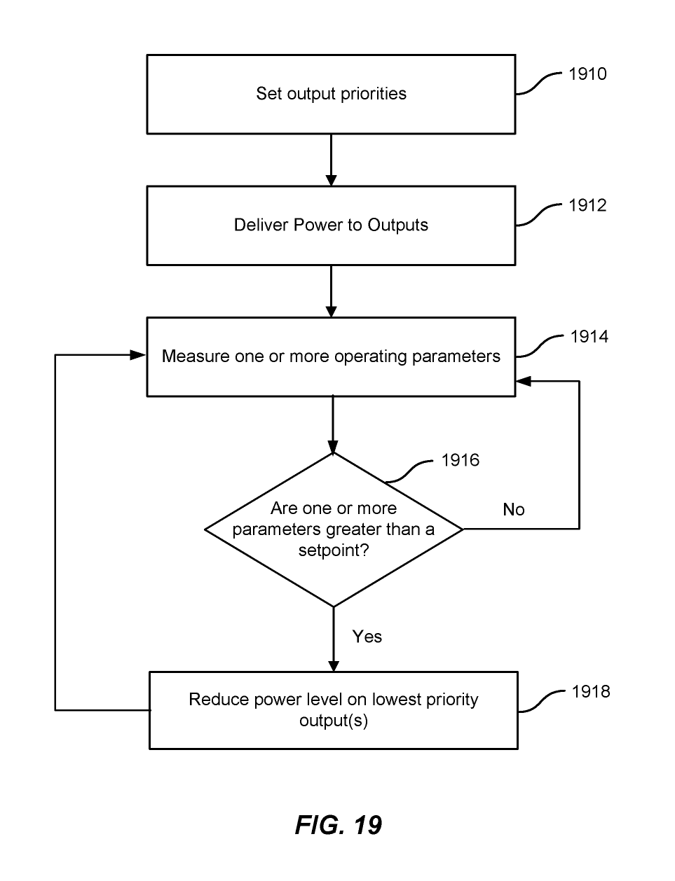

FIG. 19 is a simplified flowchart illustrating a method of operating a power adapter having multiple outputs according to an embodiment of the present invention. As described herein, a first output port of the multiple output ports can be rated at a first output power level and a second output port of the multiple output ports can be rated at a second output power level less than the first output power level, providing ports that are appropriate for powering/charging of a laptop at a higher power level and powering/charging of a tablet at a lower power level.

The method includes setting an output priority for each of the multiple outputs (1910) and providing an output power at each of the multiple outputs (1912). Additional description related setting the output priorities is provided in relation to FIG. 11 discussed above. By moving the tiles associated with the devices up or down, the priority associated with each device can be modified to various levels such as the High, Medium, and Low priorities illustrated in FIG. 11.

The method also includes measuring one or more operating parameters of the power adapter (1914) and determining if at least one of the one or more operating parameters are greater than a setpoint (1916). The monitoring process illustrated in FIG. 8 can work in conjunction with the measuring process illustrated in FIG. 19.

If the one or more operating parameters are not greater than a setpoint, then the method returns to the measurement process at 1914. If, however, the one or more operating parameters are greater than the setpoint, then the method includes reducing the output power associated with at least one of the multiple output ports (1918). After reducing the output power, the method returns to the measurement process at 1914. Reductions in the output power can include performing a PWM process at the at least one of the multiple output ports. Alternatively, the power consumed by the lower priority device can be reduced by the device in response to a command or other modification provided by the power adapter.

When the one or more operating parameters are again greater than the setpoint, the power level is reduced on the next lowest priority output (1918). In this method, multiple devices are concurrently charged until a setpoint (e.g., output power or temperature of the power adapter) is reached. The power available to the lowest priority device is then reduced. If additional power reduction is needed, then the next lowest priority device is provided with reduced or no power.

It should be noted that although not illustrated in FIG. 19, if the parameter that resulted in power reduction returns to a level less than the setpoint, then the lower priority devices can be added back in by restoring some or all of the initial power at the output ports associated with the lower priority devices. One of ordinary skill in the art would recognize many variations, modifications, and alternatives.

It should be appreciated that the specific steps illustrated in FIG. 19 provide a particular method of setting charging priority according to an embodiment of the present invention. Other sequences of steps may also be performed according to alternative embodiments. For example, alternative embodiments of the present invention may perform the steps outlined above in a different order. Moreover, the individual steps illustrated in FIG. 19 may include multiple sub-steps that may be performed in various sequences as appropriate to the individual step. Furthermore, additional steps may be added or removed depending on the particular applications. One of ordinary skill in the art would recognize many variations, modifications, and alternatives.

Although embodiments in FIGS. 10-18 are illustrated in portrait mode, landscape mode is included within the scope of the present invention and the present invention is not limited to the use of portrait mode.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A variable output power supply comprising:
a power unit comprising:
a housing including an output port;
one or more accessories disposed in the housing; and
a controller disposed in the housing and in communication with the output port; and
a power cable, wherein the controller is operable to modify operation of the output port in response, at least in part, to insertion of the power cable in the output port.

2. The variable output power supply of claim 1 wherein the one or more accessories comprise a battery.

3. The variable output power supply of claim 1 wherein the one or more accessories comprises a memory.

4. The variable output power supply of claim 1 wherein the one or more accessories comprise at least one of a WiFi hotspot, an LED projector, a speakerphone, or an internet phone.

5. The variable output power supply of claim 1 wherein insertion of the power cable in the output port is operable to modify an output voltage of the output port.

6. The variable output power supply of claim 1 wherein the output port complies with a USB standard

7. The variable output power supply of claim 1 wherein the power cable comprises a predetermined pin that is grounded.

8. The variable output power supply of claim 1 wherein the power cable comprises at least one of a voltage source or a signal source.

9. The variable output power supply of claim 1 further comprising a keyhole adjacent the output port, wherein the power cable comprises a key operable to be inserted into the keyhole.

10. The variable output power supply of claim 9 wherein the output port comprises a first output port and the keyhole is adjacent a first side of the first output port, the variable output power supply further comprising a second output port adjacent a second side of the first output port.

11. A method of operating a variable output power supply including an AC adapter and a battery, the method comprising:
setting an output voltage of an output of the variable output power supply to a default voltage;
determining a configuration of an output cable;
modifying the output voltage of the output of the variable output power supply as a function of the cable configuration; and
coupling either the AC adapter or the battery to the output of the variable output power supply.

12. The method of claim 11 wherein coupling either the AC adapter or the battery to the output of the variable output power supply comprises receiving a selection of the AC adapter or the battery.

13. The method of claim 12 wherein receiving the selection comprises receiving an input from a mobile application.

14. The method of claim 11 wherein modifying the output voltage comprises increasing the output voltage.

15. The method of claim 14 wherein increasing the output voltage comprises increasing the output voltage from 5 V to 19.5 V.

16. The method of claim 11 wherein modifying the output voltage comprises decreasing the output voltage.

17. The method of claim 11 wherein the default voltage is 5V.

18. The method of claim 11 wherein the default voltage is compliant with the USB standard.

19. The method of claim 11 wherein the battery is disposed in a housing of the variable output power supply.

20. The method of claim 11 wherein the variable output power supply comprises a first output port, a keyhole adjacent a first side of the first output port, and a second output port adjacent a second side of the first output port, wherein the output cable comprises a key operable to be inserted into the keyhole.
